(19) United States
(12) Patent Application Publication
(10) Pub. No.: US 2026/0136904 A1
(43) Pub. Date: May 14, 2026

(54) METHOD OF FABRICATING A SEMICONDUCTOR DEVICE

(71) Applicant: SAMSUNG ELECTRONICS CO., LTD., Suwon-si (KR)

(72) Inventors: Eunshoo HAN, Suwon-si (KR); Byeung Chul KIM, Suwon-si (KR)

(73) Assignee: SAMSUNG ELECTRONICS CO., LTD., Suwon-si (KR)

(21) Appl. No.: 19/076,654

(22) Filed: Mar. 11, 2025

(30) Foreign Application Priority Data
Nov. 8, 2024 (KR) 10-2024-0158390

(51) Int. Cl. H01L 21/768; H10B 12/00; H10B 61/00; H10B 63/10

(52) U.S. Cl. CPC H10W 20/071; H10B 12/01; H10B 61/20; H10B 63/10

(57) ABSTRACT

A method of fabricating a semiconductor device may include forming active patterns on a substrate. The forming the active patterns may include forming a first line pattern and a second line pattern, which extend in a first direction and are spaced apart from each other in a second direction perpendicular to the first direction, on the substrate, selectively forming a protection pattern on the first line pattern, forming an etching pattern on the first and second line patterns to extend in a third direction crossing the first and second directions, and removing a portion of the second line pattern overlapped with the etching pattern.

### CROSS-REFERENCE TO RELATED APPLICATION

This application is based on and claims priority under 35 U.S.C. § 119 to Korean Patent Application No. 10-2024-0158390, filed on Nov. 8, 2024, in the Korean Intellectual Property Office, the entire contents of which are hereby incorporated by reference.

### BACKGROUND

One or more example embodiments relate to a method of fabricating a semiconductor device.

Due to small-sized, multifunctional, and/or low-cost characteristics, semiconductor devices play an important role in the electronics industry. The semiconductor devices are classified into a semiconductor memory device for storing data, a semiconductor logic device for processing data, and a hybrid semiconductor device including both a memory element and a logic element.

With a recent trend of high speed and low power consumption of electronic devices, semiconductor devices in the electronic devices are required to have a high operating speed and/or a low operating voltage, and accordingly, an integration density of the semiconductor device needs to increase. However, as the integration density of the semiconductor device increases, the semiconductor device may suffer from deteriorated electrical characteristics and low production yield. Accordingly, studies are being conducted to improve the electrical characteristics and production yield of the semiconductor device.

### SUMMARY

One or more example embodiments of the disclosure provide a semiconductor device with improved electrical and reliability characteristics and a method of fabricating the same.

According to an aspect of an example embodiment of the disclosure, a method of fabricating a semiconductor device may include forming active patterns on a substrate. The forming of the active patterns may include: forming, on the substrate, a first line pattern and a second line pattern, which extend in a first direction and are spaced apart from each other in a second direction perpendicular to the first direction; selectively forming a protection pattern on the first line pattern; forming an etching pattern on the first line pattern and the second line pattern, the etching pattern extending in a third direction crossing the first direction and the second direction; and removing a portion of the second line pattern overlapped with the etching pattern.

According to an aspect of an example embodiment of the disclosure, a method of fabricating a semiconductor device may include forming active patterns on a substrate. The forming of the active patterns may include: forming, on the substrate, line patterns, which extend in a first direction and are spaced apart from each other in a second direction perpendicular to the first direction; forming a protection pattern on the line patterns; forming, on the line patterns, etching patterns extending in a third direction crossing the first direction and the second direction, each of the line patterns including a first portion and a second portion, which are overlapped with the etching patterns, the protection pattern being between the first portion and the etching patterns; and selectively removing the second portion.

According to an aspect of an example embodiment of the disclosure, a method of fabricating a semiconductor device may include: forming, on the substrate, line patterns, which extend in a first direction and are spaced apart from each other in a second direction perpendicular to the first direction; forming a protection pattern on the line patterns; forming, on the line patterns, etching patterns extending in a third direction crossing the first direction and the second direction, each of the line patterns including a first portion and a second portion, which are overlapped with the etching patterns, the protection pattern being between the first portion and the etching patterns; and selectively removing the second portion.

### BRIEF DESCRIPTION OF DRAWINGS

The above and other aspects and features of the disclosure will become more apparent by describing in detail example embodiments thereof with reference to the attached drawings.

FIG. 1 is a plan view illustrating a semiconductor device according to one or more embodiments of the disclosure.

FIG. 2 is an enlarged view illustrating a portion Z of FIG. 1.

FIG. 3A is a cross-sectional view taken along a line A-A′ of FIG. 2.

FIG. 3B is a cross-sectional view taken along a line B-B′ of FIG. 2.

FIG. 3C is a cross-sectional view taken along a line C-C′ of FIG. 2.

FIG. 3D is a cross-sectional view taken along a line D-D′ of FIG. 2.

FIG. 3E is a cross-sectional view taken along a line E-E′ of FIG. 2.

FIGS. 4, 6, 9, and 13 are enlarged views illustrating a method of fabricating a semiconductor device according to one or more embodiments of the disclosure.

FIGS. 5A, 5B, 7A, 7B, 8A, 8B, 10A, 10B, 11A, 11B, 12A, 12B, 14A, 14B, 15A, and 15B are cross-sectional views illustrating a method of fabricating a semiconductor device according to one or more embodiments of the disclosure.

FIGS. 16, 18, 21, and 25 are an enlarged views illustrating a method of fabricating a semiconductor device according to one or more embodiments of the disclosure.

FIGS. 17A, 17B, 19A, 19B, 20A, 20B, 22A, 22B, 23A, 23B, 24A, 24B, 26A, 26B, 27A, and 27B are cross-sectional views illustrating a method of fabricating a semiconductor device according to one or more embodiments of the disclosure.

### DETAILED DESCRIPTION

Example embodiments of the disclosures will now be described more fully with reference to the accompanying drawings, in which example embodiments are shown.

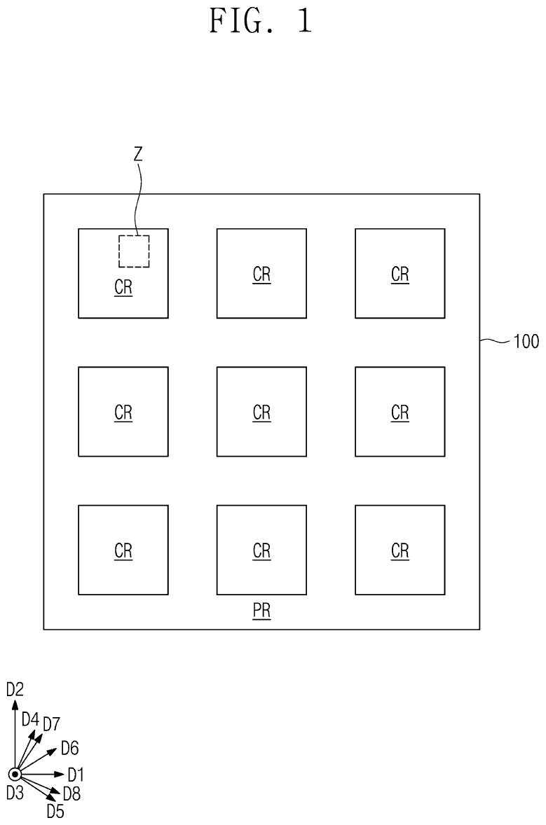

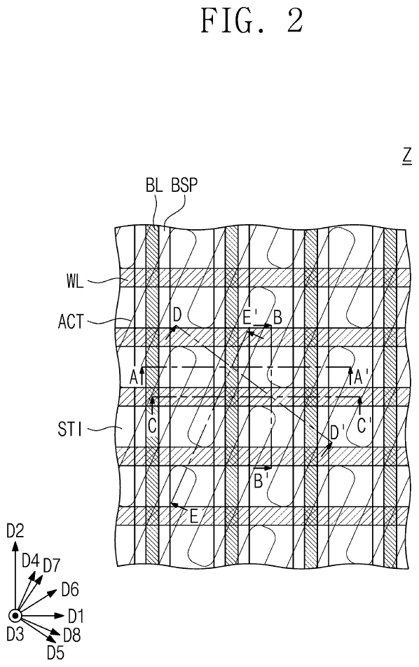

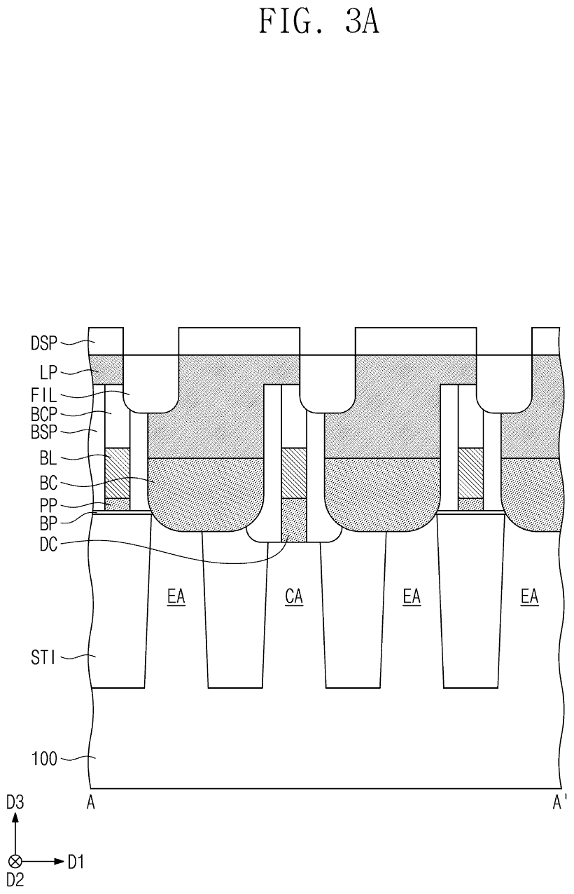

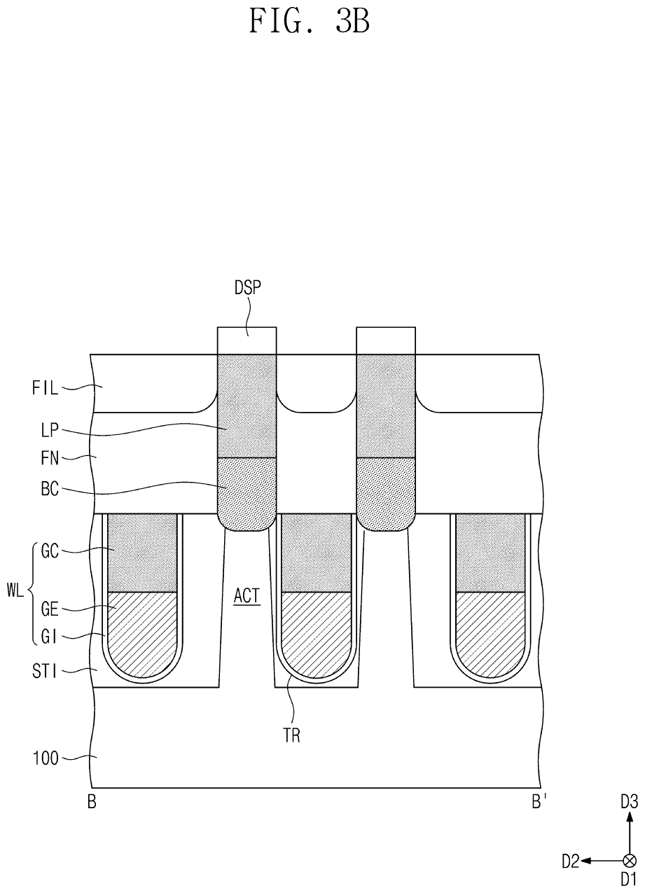

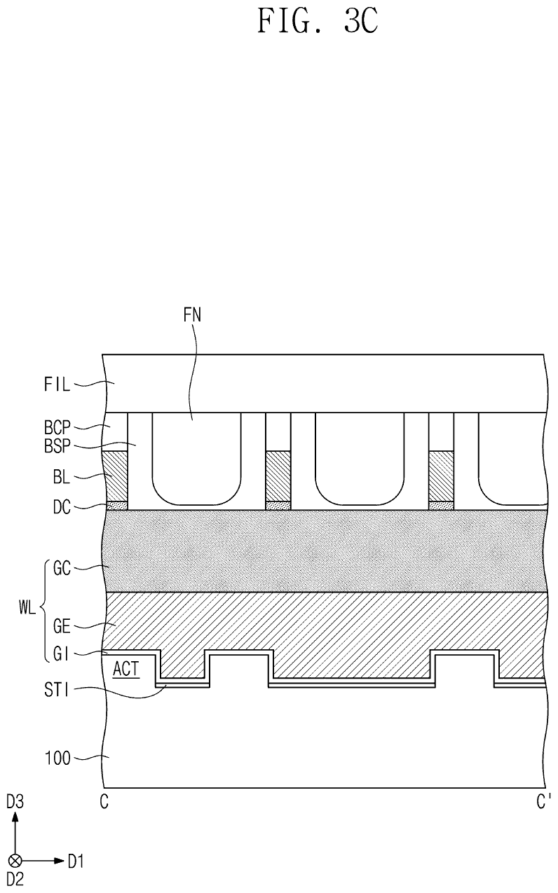

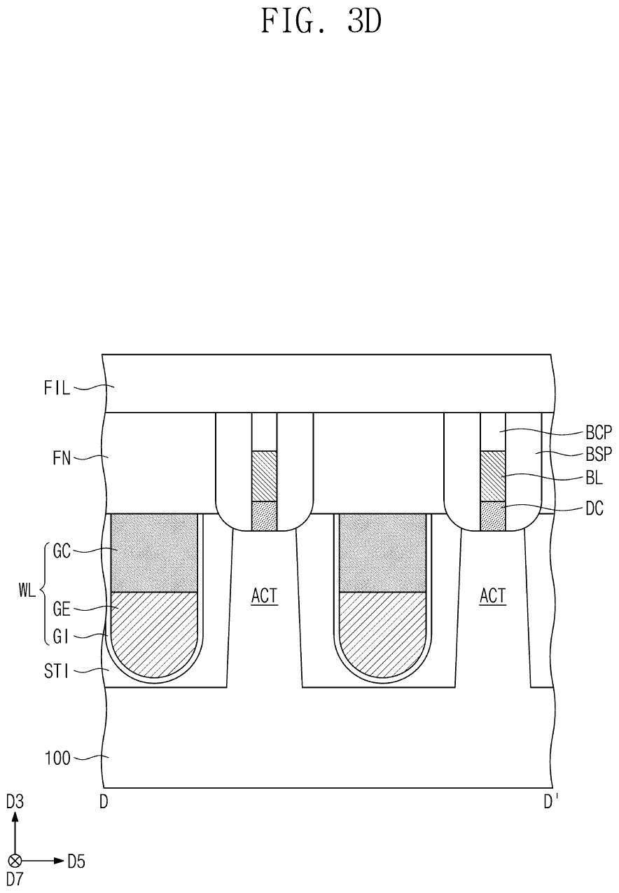

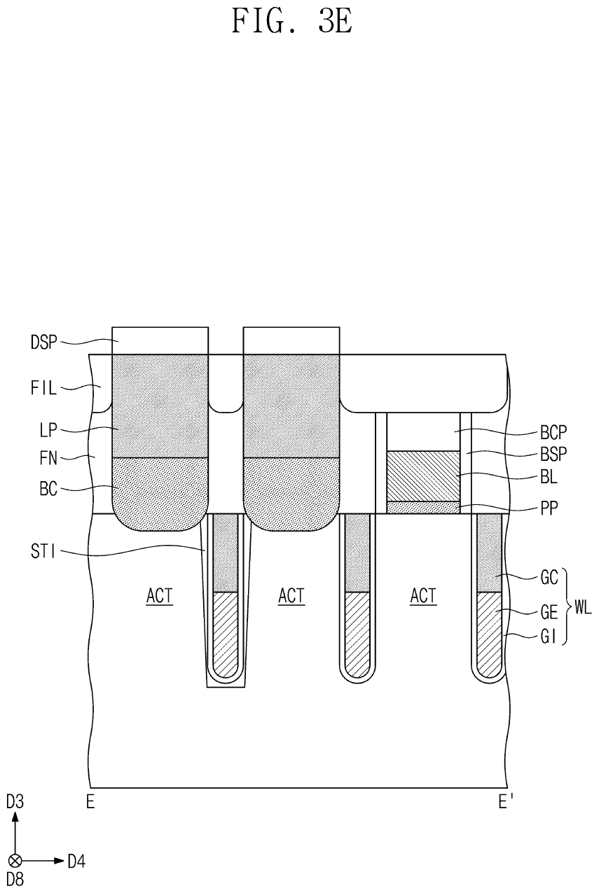

FIG. 1 is a plan view illustrating a semiconductor device according to one or more embodiments of the disclosure. FIG. 2 is an enlarged view illustrating a portion Z of FIG. 1. FIG. 3A is a cross-sectional view taken along a line A-A′ of FIG. 2. FIG. 3B is a cross-sectional view taken along a line B-B′ of FIG. 2. FIG. 3C is a cross-sectional view taken along a line C-C′ of FIG. 2. FIG. 3D is a cross-sectional view taken along a line D-D′ of FIG. 2. FIG. 3E is a cross-sectional view taken along a line E-E′ of FIG. 2.

Referring to FIGS. 1, 2, 3A, 3B, 3C, 3D, and 3E, a semiconductor device may include a substrate 100. In an embodiment, the substrate 100 may be a semiconductor substrate. As an example, the substrate 100 may be formed of or include silicon, germanium, silicon-germanium, GaP, or GaAs. In an embodiment, the substrate 100 may be a silicon-on-insulator (SOI) substrate or a germanium-on-insulator (GOI) substrate. The substrate 100 may have a plate-shaped structure having a bottom surface extending in a first direction D1 and a second direction D2. The first and second directions D1 and D2 may not be parallel to each other. As an example, the first and second directions D1 and D2 may be horizontal directions that are orthogonal to each other.

The substrate 100 may include cell regions CR and a peripheral region PR enclosing the cell regions CR. Each of the cell regions CR may include a cell circuit (e.g., a memory integrated circuit). The peripheral region PR may include various peripheral circuits, which are used to operate the cell circuit, and the peripheral circuits may be electrically connected to the cell circuit.

The substrate 100 may include active patterns ACT. Upper portions of the substrate 100, which protrude in a third direction D3, may be defined as the active patterns ACT. The third direction D3 may not be parallel to the first and second directions D1 and D2. As an example, the third direction D3 may be a vertical direction that is orthogonal to the first and second directions D1 and D2.

The active patterns ACT may be island-shaped patterns which are separated from each other. Each of the active patterns ACT may extend in a fourth direction D4. The fourth direction D4 may not be parallel to the first direction D1, the second direction D2, and the third direction D3. In an embodiment, the fourth direction D4 may be a horizontal direction orthogonal to the third direction D3.

Each of the active patterns ACT may be a bar-shaped pattern that is elongated in the fourth direction D4 parallel to the bottom surface of the substrate 100. The active patterns ACT may be spaced apart from each other in the fourth direction D4 and an eighth direction D8. The eighth direction D8 may be orthogonal to the fourth direction D4. The eighth direction D8 may not be parallel to the first, second, third, and fourth directions D1, D2, D3, and D4. The eighth direction D8 may be a horizontal direction that is orthogonal to the third and fourth directions D3 and D4.

A device isolation layer STI may be provided to define the active patterns ACT. Each of the active patterns ACT may be enclosed by the device isolation layer STI. The device isolation layer STI may include an insulating material.

The active pattern ACT may include edge portions EA, which are spaced apart from each other in the fourth direction D4, and a center portion CA therebetween. The edge portions EA may be two portions of the active pattern ACT that are opposite to each other in the fourth direction D4. The center portion CA may be a portion of the active pattern ACT interposed between the edge portions EA, and in particular, the center portion CA may be a portion of the active pattern ACT interposed between a pair of word lines WL, which will be described below. The edge portions EA and the center portion CA may be doped with impurities (e.g., n- or p-type impurities).

The word line WL may be provided to cross the active patterns ACT and the device isolation layer STI. In an embodiment, a plurality of word lines WL may be provided. The word lines WL may be spaced apart from each other in the second direction D2. A pair of the word lines WL, which are adjacent to each other in the second direction D2, may be provided to cross the active pattern ACT. The word lines WL may be placed in trench regions TR, respectively, which are provided in the active patterns ACT and the device isolation layer STI.

Each of the word lines WL may include a gate electrode GE, a gate dielectric pattern GI, and a gate capping pattern GC. The gate electrode GE may penetrate the active patterns ACT and the device isolation layer STI in the first direction D1. The gate dielectric pattern GI may be interposed between the gate electrode GE and the active patterns ACT and between the gate electrode GE and the device isolation layer STI, in the cross-sectional view taken along in the first direction D1. The gate capping pattern GC may be provided on the gate electrode GE to cover a top surface of the gate electrode GE, in the cross-sectional view taken along in the first direction D1 or the second direction D2. The gate electrode GE may include a conductive material. As an example, the gate electrode GE may be a single layer, which is made of or includes a single material, or a composite layer including two or more materials. In an embodiment, the gate dielectric pattern GI may include at least one of silicon oxide (SiO₂) or high-k dielectric materials. In the present specification, the high-k dielectric material may be defined as a material having a dielectric constant higher than that of silicon oxide. In an embodiment, the gate capping pattern GC may be formed of or include silicon nitride (SiN).

A buffer pattern BP may be provided on the substrate 100. The buffer pattern BP may cover the active patterns ACT and the device isolation layer STI. The buffer pattern BP may be a single layer or a composite layer. In an embodiment, the buffer pattern BP may include at least one of silicon oxide (SiO₂), silicon nitride (SiN), or silicon oxynitride (SiON).

First recess regions may be provided in an upper portion of each of the active patterns ACT and an upper portion of the device isolation layer STI, which are adjacent to each other.

A bit line contact DC may be interposed between the center portion CA of the active pattern ACT and a bit line BL, which will be described below. In an embodiment, a plurality of bit line contacts DC may be provided. The bit line contacts DC may be spaced apart from each other in the first and second directions D1 and D2. The bit line contact DC may electrically connect a corresponding one of the bit lines BL to the center portion CA of a corresponding one of the active patterns ACT. The bit line contact DC may be formed of or include at least one of doped or undoped polysilicon or metallic materials (e.g., Ti, Mo, W, Cu, Al, Ta, Ru, and Ir).

The bit line BL may be provided on the bit line contact DC. The bit line BL on the bit line contact DC may extend in the second direction D2. In an embodiment, a plurality of bit lines BL may be provided. The bit lines BL may be spaced apart from each other in the first direction D1. As an example, the bit line BL may be formed of or include at least one of metallic materials (e.g., Ti, Mo, W, Cu, Al, Ta, Ru, and Ir).

An insulating pattern PP may be provided between the bit line BL and the buffer pattern BP and between the bit line contacts DC, which are adjacent to each other in the first direction D1. In an embodiment, a plurality of insulating patterns PP may be provided. The insulating patterns PP may be spaced apart from each other in the first and second directions D1 and D2. The insulating pattern PP may have a top surface that is located at substantially the same height as (i.e., coplanar with) a top surface of the bit line contact DC.

A bit line capping pattern BCP may be provided on the bit line BL. The bit line capping pattern BCP may extend along the bit line BL and in the second direction D2. In an embodiment, a plurality of bit line capping patterns BCP may be provided. The bit line capping patterns BCP may be spaced apart from each other in the first direction D1. The bit line capping pattern BCP may be vertically overlapped with the bit line BL. The bit line capping pattern BCP may include a single layer or a plurality of layers.

A bit line spacer BSP may be provided on a side surface of the bit line contact DC, a side surface of the bit line BL, and a side surface of the bit line capping pattern BCP. The bit line spacer BSP on the side surface of the bit line BL may extend in the second direction D2. The bit line spacer BSP may be provided to fill the first recess region and may extend along the side surface of the bit line capping pattern BCP and in the third direction D3. In an embodiment, a plurality of bit line spacers BSP may be provided. The bit line spacers BSP may be spaced apart from each other in the first direction D1. The bit line spacer BSP may be formed of or include at least one of silicon oxide (SiO₂), silicon nitride (SiN), silicon oxycarbide (SiOC), and silicon oxycarbonitride (SiOCN). The bit line spacer BSP may include a single layer or a plurality of layers.

A storage node contact BC may be provided between the bit lines BL, which are adjacent to each other in the first direction D1. In an embodiment, a plurality of storage node contacts BC may be provided. The storage node contacts BC may be spaced apart from each other in the first and second directions D1 and D2. The storage node contacts BC, which are adjacent to each other in the first direction D1, may be spaced apart from each other with the bit line BL interposed therebetween in the first direction D1. The storage node contacts BC, which are adjacent to each other in the second direction D2, may be spaced apart from each other, with a fence pattern FN to be described below interposed therebetween in the second direction D2. Each of the storage node contacts BC may be provided to fill a second recess region, which is provided on the edge portion EA of a corresponding one of the active patterns ACT, and may be connected to a corresponding one of the edge portions EA. In an embodiment, the storage node contact BC may be formed of or include at least one of doped or undoped polysilicon or metallic materials (e.g., Ti, Mo, W, Cu, Al, Ta, Ru, and Ir).

The fence pattern FN may be provided on the word line WL and may be interposed between the bit lines BL, which are adjacent to each other in the first direction D1. The fence pattern FN on the word line WL may be interposed between the storage node contacts BC, which are adjacent to each other in the second direction D2. In an embodiment, a plurality of fence patterns FN may be provided. The fence patterns FN may be spaced apart from each other in the first and second directions D1 and D2. The fence patterns FN, which are adjacent to each other in the first direction D1, may be spaced apart from each other, with the bit line BL interposed therebetween, in the first direction D1. The fence patterns FN, which are adjacent to each other in the second direction D2, may be spaced apart from each other, with the storage node contact BC interposed therebetween in the second direction D2. In an embodiment, the fence pattern FN may be formed of or include at least one of silicon oxide (SiO₂), silicon nitride (SiN), silicon oxycarbide (SiOC), or silicon oxycarbonitride (SiOCN).

Landing pads LP may be provided. The landing pad LP may be provided on the storage node contact BC. The landing pad LP may include a conductive material. In an embodiment, the landing pad LP may be formed of or include a metallic material. In an embodiment, a metal silicide layer may be provided between the storage node contact BC and the landing pad LP. In an embodiment, a barrier layer may be provided between the storage node contact BC and the landing pad LP.

The landing pad LP may include an upper portion and a lower portion. An upper portion of the landing pad LP may be disposed at a level higher than the bit line capping pattern BCP. A lower portion of the landing pad LP may be connected to the storage node contact BC. The upper portion of the landing pad LP may be provided on the lower portion of the landing pad LP. A portion of the upper portion of the landing pad LP may be overlapped with a portion of the storage node contact BC in the third direction D3. In an embodiment, an entire portion of the landing pad LP may be disposed at a level higher than the bit line capping pattern BCP.

A filling pattern FIL may be provided on the fence pattern FN. The filling pattern FIL may separate the landing pads LP from each other. The filling pattern FIL may be provided to enclose the landing pad LP. The filling pattern FIL may include an insulating material.

A data storage pattern DSP may be provided on the landing pad LP. In an embodiment, a plurality of data storage patterns DSP may be provided, and the data storage patterns DSP may be spaced apart from each other in the first and second directions D1 and D2. Each of the data storage patterns DSP may be vertically overlapped with at least a portion of a corresponding one of the landing pads LP. As an example, each of the data storage patterns DSP may be vertically overlapped with the entire portion of the corresponding landing pad LP. As another example, each of the data storage patterns DSP may be shifted from the landing pad LP in the first direction D1 or an opposite direction of the first direction D1 and may be vertically overlapped with a portion of the landing pad LP. The data storage pattern DSP may be electrically connected to the edge portion EA of the corresponding active pattern ACT through the corresponding landing pad LP and the corresponding storage node contact BC.

In an embodiment, the data storage pattern DSP may be a capacitor including a bottom electrode, a dielectric layer, and a top electrode. In this case, the semiconductor device may be a dynamic random access memory (DRAM) device. In an embodiment, the data storage pattern DSP may include a magnetic tunnel junction pattern. In this case, the semiconductor device may be a magnetic random access memory (MRAM) device. In an embodiment, the data storage pattern DSP may be formed of or include a phase-change material or a variable resistance material. In this case, the semiconductor device may be a phase-change random access memory (PRAM) device or a resistive random access memory (ReRAM) device. However, the disclosure is not limited to these examples, and the data storage pattern DSP may include various structures and/or materials which can be used to store data.

### Embodiment 1

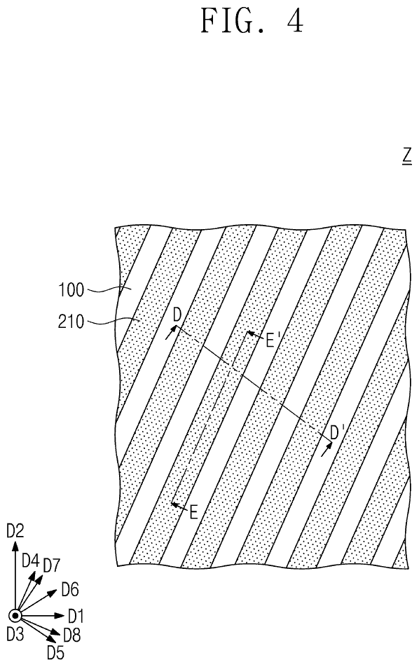

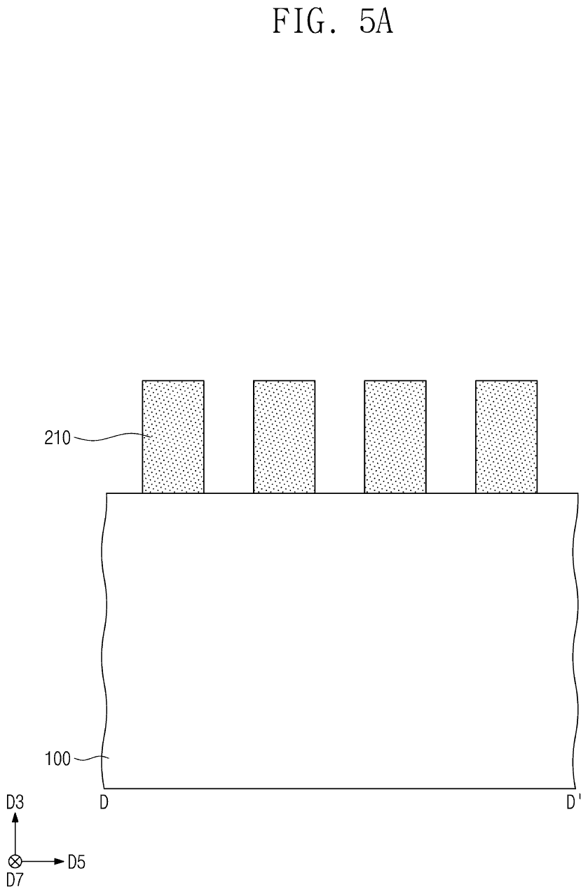

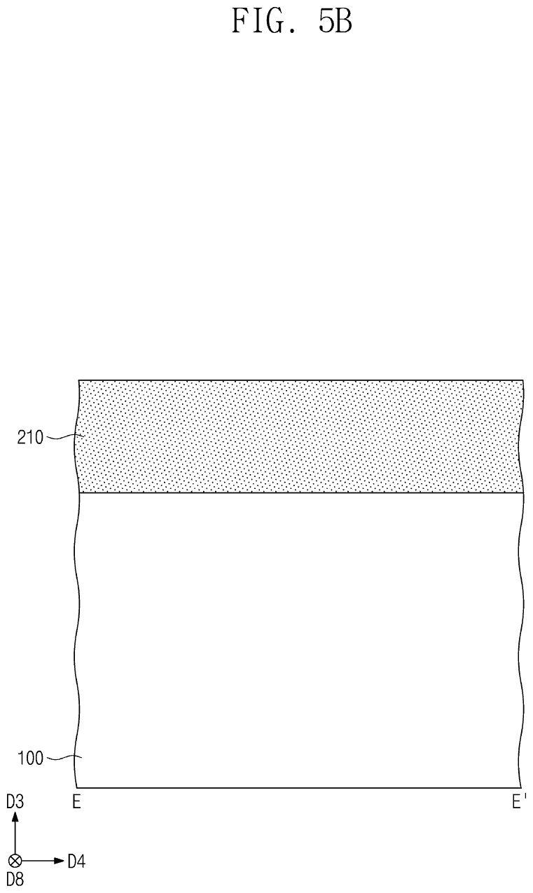

FIGS. 4, 6, 9, and 13 are enlarged views illustrating a method of fabricating a semiconductor device according to one or more embodiments of the disclosure. FIGS. 5A, 5B, 7A, 7B, 8A, 8B, 10A, 10B, 11A, 11B, 12A, 12B, 14A, 14B, 15A, and 15B are cross-sectional views illustrating a method of fabricating a semiconductor device according to one or more embodiments of the disclosure.

FIGS. 5A and 5B are cross-sectional views taken along a line D-D′ and a line E-E′ of FIG. 4, respectively. Referring to FIGS. 4, 5A, and 5B, line patterns 210 may be formed on the substrate 100. The line patterns 210 may be line-shaped patterns extending in the fourth direction D4. The line patterns 210 may be spaced apart from each other in the eighth direction D8. The eighth direction D8 may be perpendicular to the fourth direction D4.

The line patterns 210 may be formed in regions, in which the active patterns ACT are to be formed, when viewed in a plan view. In an embodiment, the line patterns 210 may be formed through a patterning process. The patterning process may include a single patterning or a multiple patterning process. The multiple patterning process may include a double patterning process (DPT), a triple patterning process (TPT), or a quadruple process (QPT).

The line patterns 210 may include an insulating material and/or a polymer. The insulating material may include at least one of oxide materials (e.g., silicon oxide) and/or nitride materials (e.g., silicon nitride).

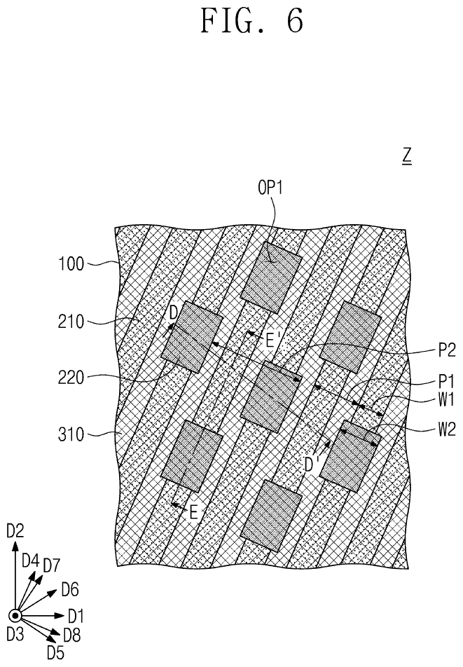

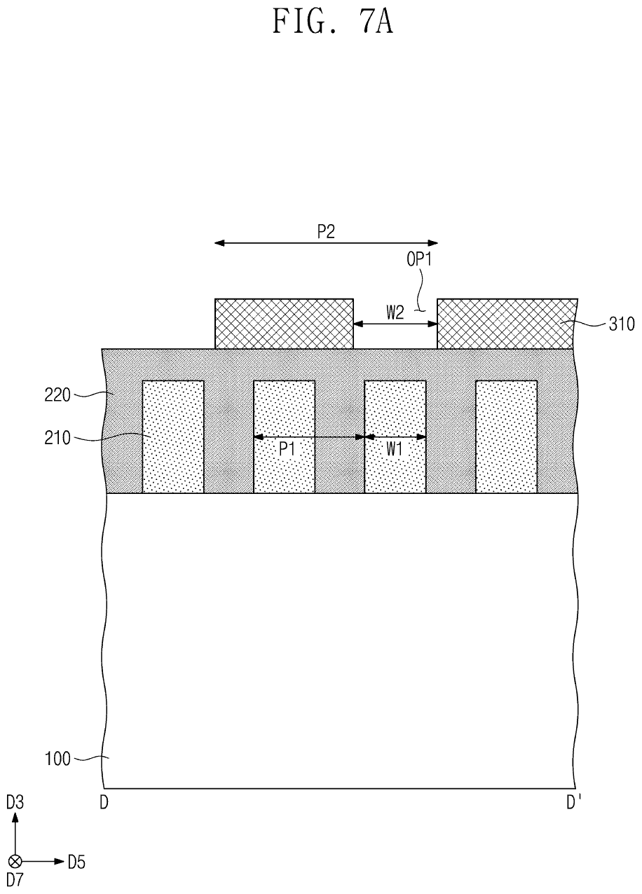

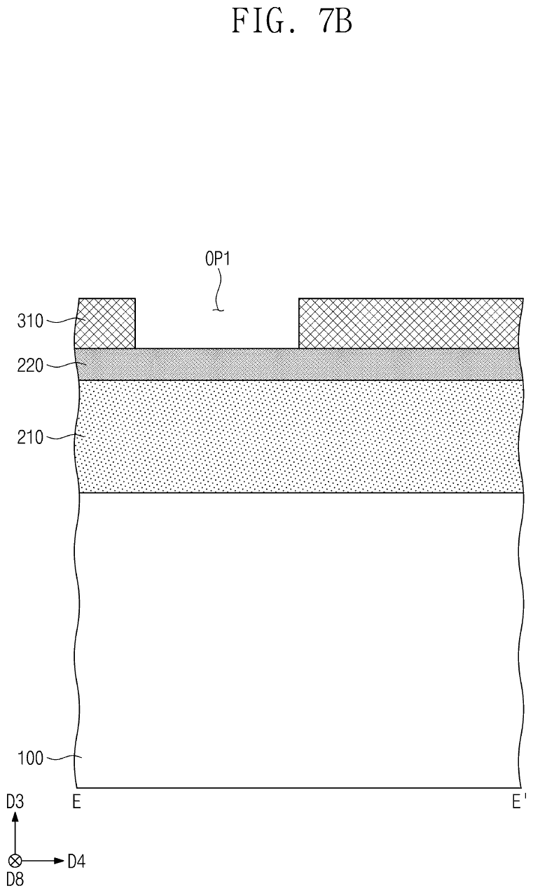

FIGS. 7A and 7B are cross-sectional views taken along a line D-D′ and a line E-E′ of FIG. 6, respectively. Referring to FIGS. 6, 7A, and 7B, a first mask layer 220 may be formed on the line patterns 210. A first protection pattern 310 may be formed on the first mask layer 220. The first protection pattern 310 may extend in a sixth direction D6.

A level of a top surface of the first mask layer 220 may be higher than a level of a top surface of the line patterns 210. The first mask layer 220 may include an insulating material and/or a polymer that is different from a material of the line patterns 210.

The first protection pattern 310 may have a plurality of first openings OP1. The first protection pattern 310 may be provided as a single object. A portion of the line pattern 210 may be overlapped with the first protection pattern 310 in the third direction D3, and another portion of the line pattern 210 may be overlapped with the first opening OP1 in the third direction D3.

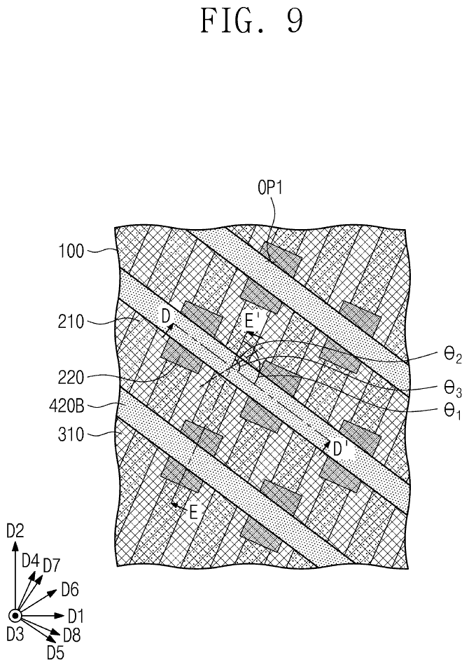

The first openings OP1 may be spaced apart from each other in the fourth direction D4 and a fifth direction D5. The fifth direction D5 may be an extension direction of etching patterns 420B, which will be described in more detail with reference to FIG. 9. As shown in FIG. 6, the first openings OP1 may be arranged to form a zigzag shape, in a plan view along the first direction D1 and the second direction D2, in a direction between the fourth direction D4 and the fifth direction D5.

The first openings OP1 may be disposed to be spaced apart from each other in the sixth direction D6 and to form a row in the sixth direction D6. The first openings OP1 may be provided to form a plurality of rows, which are spaced apart from each other in a direction perpendicular to the sixth direction D6. The relationship between the sixth direction D6, the fourth direction D4, and the fifth direction D5 will be described in more detail with reference to FIG. 9.

A width W2 of the first opening OP1 in the fifth direction D5 may be larger than a width W1 of the line pattern 210 in the fifth direction D5. A width of the first protection pattern 310 in the fifth direction D5 may be larger than the width W1 of the line pattern 210 in the fifth direction D5. In this case, it may be possible to clearly distinguish a portion of the line pattern 210, which is to be protected by the first protection pattern 310, from a portion of the line pattern 210, which is not to be protected by the first protection pattern 310.

The line patterns 210 may have a first pitch P1 in the fifth direction D5. The first openings OP1 may have a second pitch P2 in the fifth direction D5. The second pitch P2 may be larger than the first pitch P1. The second pitch P2 may be 1.5 to 2.5 times the first pitch P1, but the disclosure is not limited to this example.

In an embodiment, the formation of the first protection pattern 310 may include forming a first protection layer (not shown) and patterning the first protection layer. The patterning of the first protection layer may be performed through a photolithography process (e.g., an extreme ultraviolet (EUV) photolithography process).

The first protection pattern 310 may include an insulating material and/or a polymer.

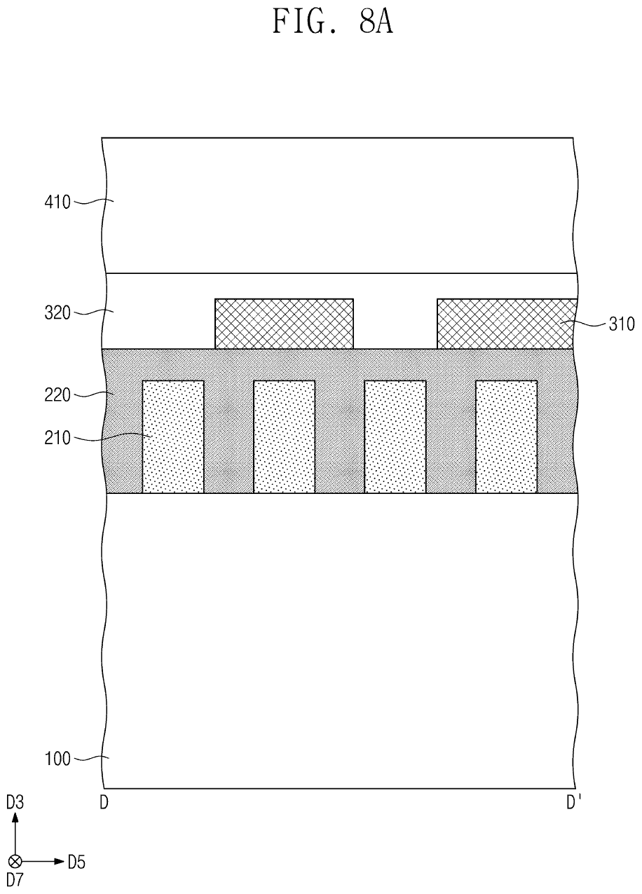

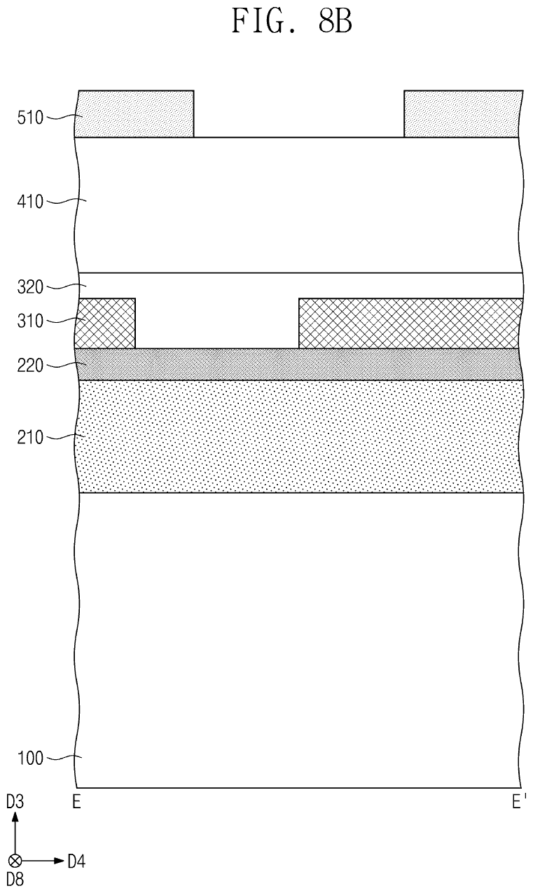

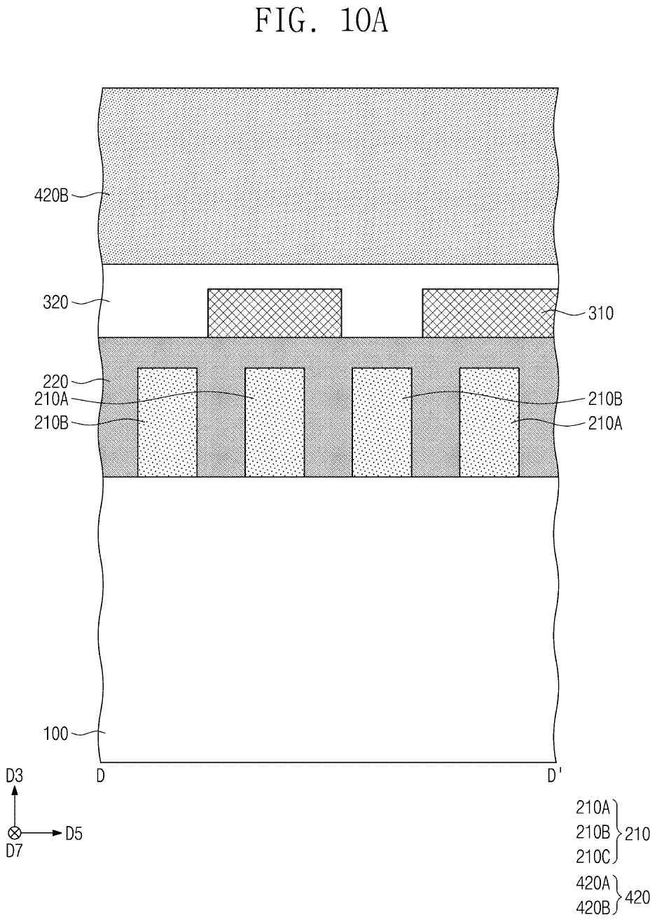

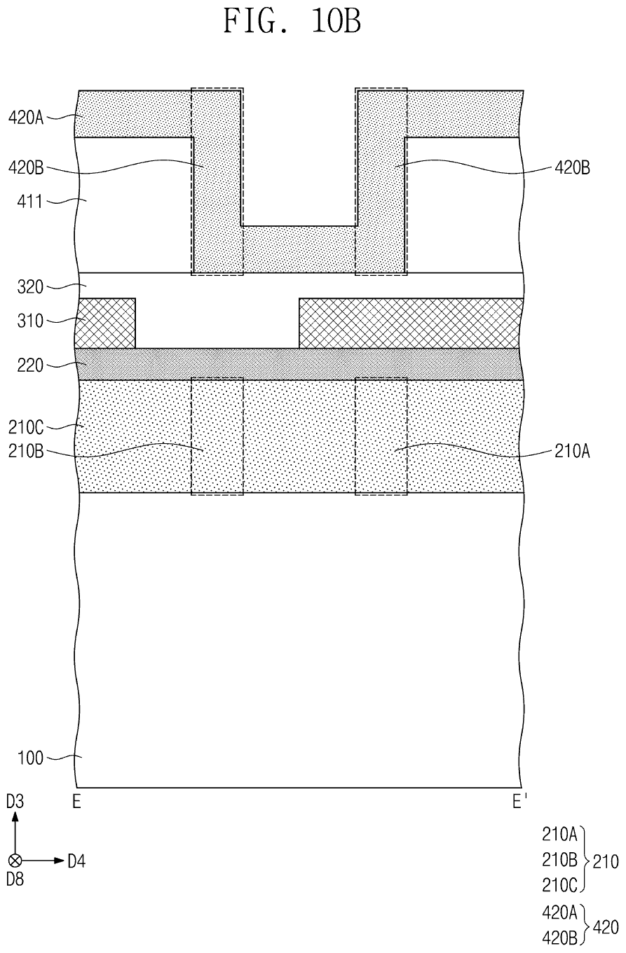

FIGS. 10A and 10B are cross-sectional views taken along a line D-D′ and a line E-E′ of FIG. 9, respectively. Referring to FIGS. 8A, 8B, 9, 10A, and 10B, a second mask layer 320 may be formed on the first protection pattern 310. An etching pattern 420B may be formed on the second mask layer 320.

The second mask layer 320 may include an insulating material and/or a polymer. The second mask layer 320 may be formed of or include a material different from the first protection pattern 310. The second mask layer 320 may include a material having an etch selectivity with respect to the first protection pattern 310.

In an embodiment, the formation of the etching pattern 420B may include forming a third mask layer 410 on the second mask layer 320, forming a first mask pattern 510 on the third mask layer 410, removing a portion of the third mask layer 410 to form a second mask pattern 411, and forming the etching pattern 420B on the second mask pattern 411.

Each of the third mask layer 410 and the first mask pattern 510 may include an insulating material and/or a polymer. In an embodiment, the formation of the first mask pattern 510 may include forming a mask layer (not shown) and patterning the mask layer. The patterning of the mask layer may be performed through a photolithography process (e.g., an Argon Fluoride (ArF) photolithography process).

The formation of the etching pattern 420B on the second mask pattern 411 may include forming an etching structure 420 on the second mask pattern 411. The formation of the etching structure 420 on the second mask pattern 411 may include depositing the etching structure 420 on top and side surfaces of the second mask pattern 411 and a top surface of the second mask layer 320 exposed by the second mask pattern 411.

The etching structure 420 may include an insulating material and/or a polymer. The etching structure 420 may include a material, which is different from the second mask pattern 411 and has an etch selectivity. In detail, the etching structure 420 may include a material having a higher etch rate than the second mask pattern 411.

The etching structure 420 may include a vertical portion and a horizontal portion 420A. The horizontal portion 420A may extend in a direction parallel to the bottom surface of the substrate 100, and the vertical portion may extend in the third direction D3. A thickness of the vertical portion in the third direction D3 may be larger than that of the horizontal portion 420A in the third direction D3. The vertical portion of the etching structure 420 may be referred to as the etching pattern 420B.

In an embodiment, a plurality of etching patterns 420B may be provided. The etching patterns 420B may be line-shaped patterns, which extend in the fifth direction D5 and are spaced apart from each other in a seventh direction D7. The seventh direction D7 may be perpendicular to both the third and fifth directions D3 and D5.

An angle between the fourth and fifth directions D4 and D5 may range from 45° to 90° or may range from 70° to 80°.

All of the fourth, fifth, and sixth directions D4, D5, and D6 may be parallel to the bottom surface of the substrate 100. The fourth, fifth, and sixth directions D4, D5, and D6 may satisfy the following [Equation 1].

$${θ}_{1} = {θ}_{2} + {θ}_{3} \qquad [ Equation 1 ]$$

θ₁ is an angle between the fourth direction D4 and the fifth direction D5, θ₂ is an angle between the fourth direction D4 and the sixth direction D6, θ₃ is an angle between the fifth direction D5 and the sixth direction D6, and at least one of θ₂ and θ₃ is an acute angle.

The line pattern 210 may include a first portion 210A, a second portion 210B, and a third portion 210C. The first portion 210A may be defined as a portion of the line pattern 210, which is overlapped with both the first protection pattern 310 and the etching pattern 420B in the third direction D3. The second portion 210B may be defined as a portion of the line pattern 210, which is overlapped with the etching pattern 420B and is not overlapped with the first protection pattern 310 in the third direction D3. The third portion 210C may be defined as a portion of the line pattern 210, which is overlapped with the horizontal portion 420A or excludes the first and second portions 210A and 210B.

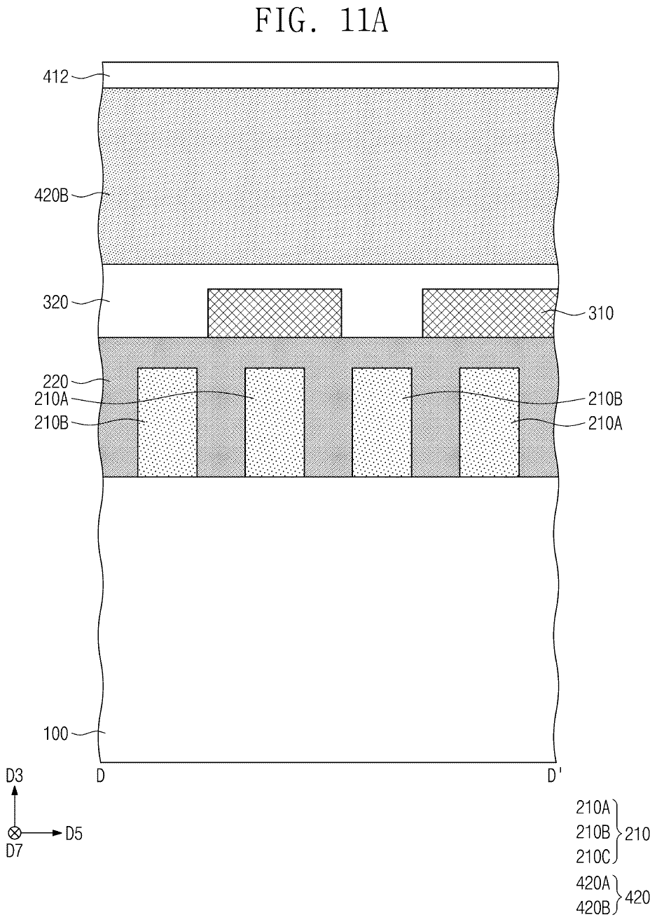

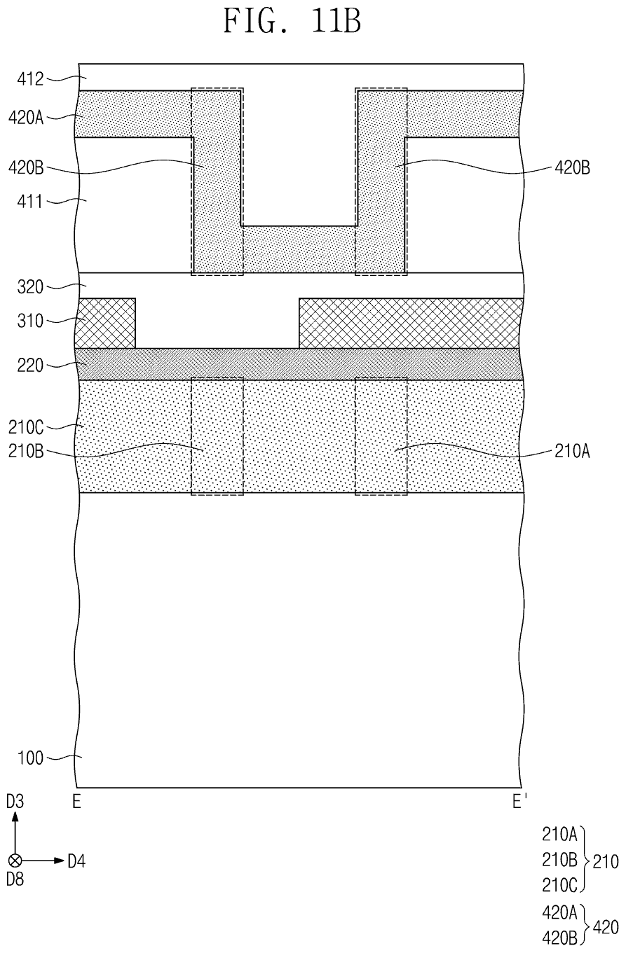

Referring to FIGS. 11A and 11B, a third mask pattern 412 may be formed on the etching structure 420. The third mask pattern 412 may include an insulating material and/or a polymer. The third mask pattern 412 may include a material which is different from the etching structure 420 and has an etch selectivity with respect to the etching structure 420. For example, the third mask pattern 412 may include a material having a slower etch rate than the etching structure 420. In an embodiment, the third mask pattern 412 may include the same material as the second mask pattern 411, but the disclosure is not limited to this example. The third mask pattern 412 may have a top surface that is parallel to the bottom surface of the substrate 100.

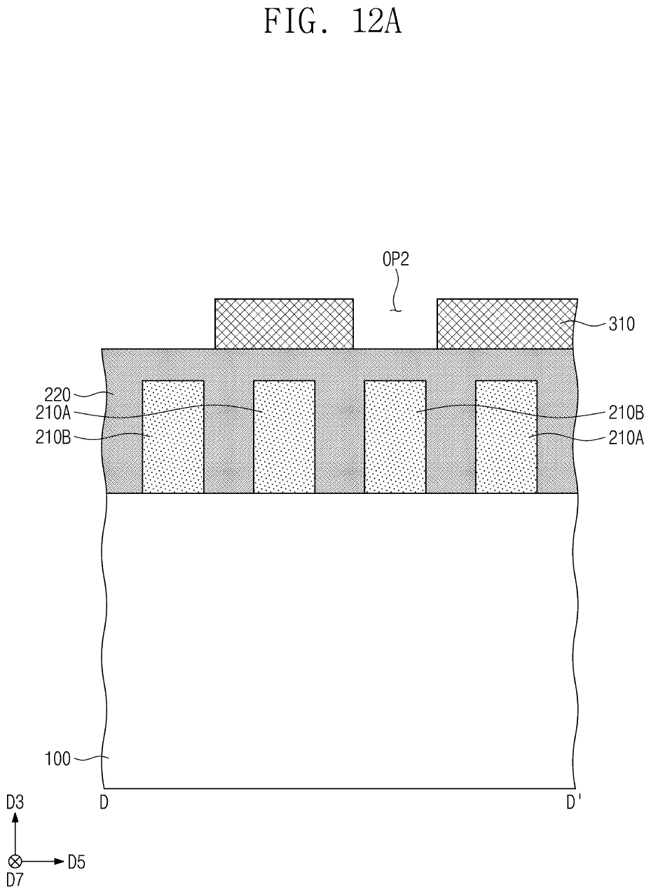

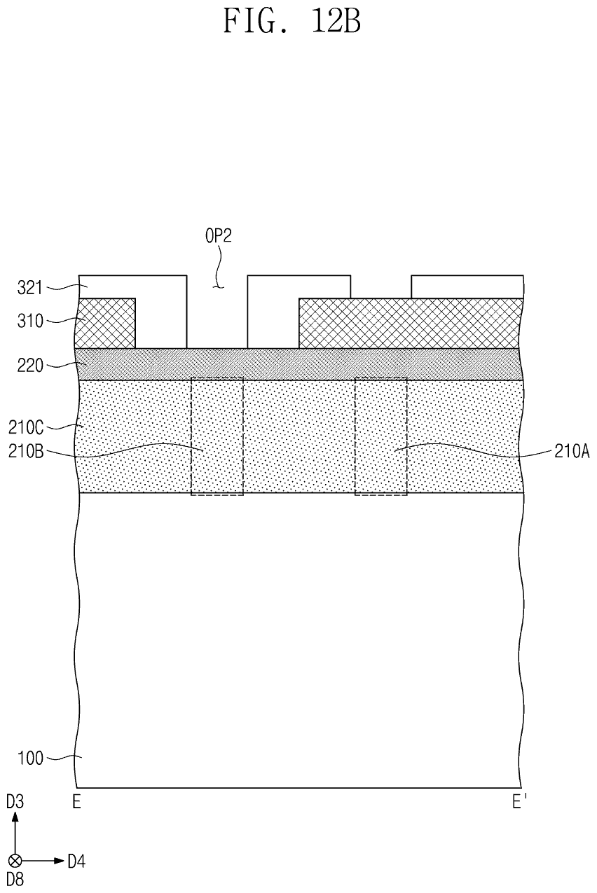

Referring to FIGS. 12A and 12B, the third mask pattern 412, the etching structure 420, the second mask pattern 411, and a portion of the second mask layer 320 may be removed. As a result of the partial removal of the second mask layer 320, a fourth mask pattern 321 may be formed, and in an embodiment, the fourth mask pattern 321 may include a plurality of second openings OP2 exposing a top surface of the first mask layer 220.

The removal of the third mask pattern 412, the etching structure 420, the second mask pattern 411, and the portion of the second mask layer 320 may include etching the third mask pattern 412, the etching structure 420, the second mask pattern 411, and the portion of the second mask layer 320. Due to an etch rate difference, the etching structure 420 may be faster etched than the second and third mask patterns 411 and 412, and in this case, the portion of the second mask layer 320 may be removed.

As a result of the partial etching of the second mask layer 320, the portion of the second mask layer 320, which is overlapped with the first and second portions 210A and 210B in the third direction D3, may be fully removed. Due to the difference in the etch rate between the first protection pattern 310 and the second mask layer 320, a portion of the top surface of the first mask layer 220, which is overlapped with the second portion 210B in the third direction D3, may be exposed, but another portion of the top surface of the first mask layer 220, which is overlapped with the first portion 210A in the third direction D3, may be covered with the first protection pattern 310.

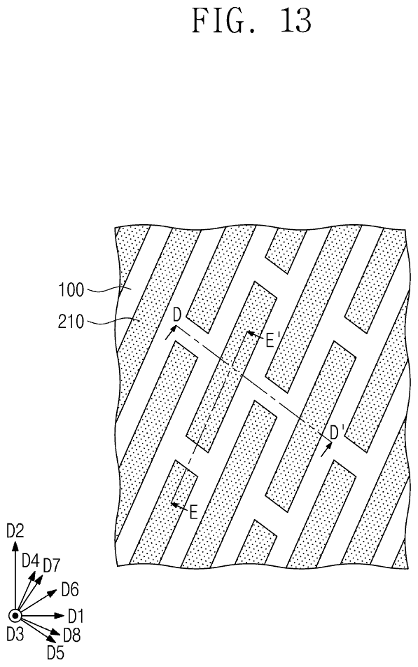

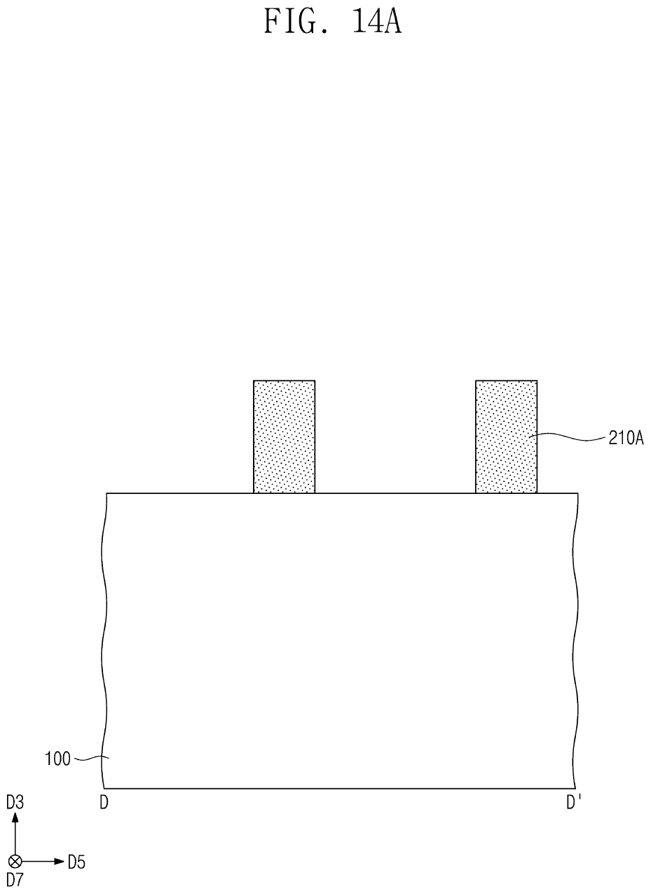

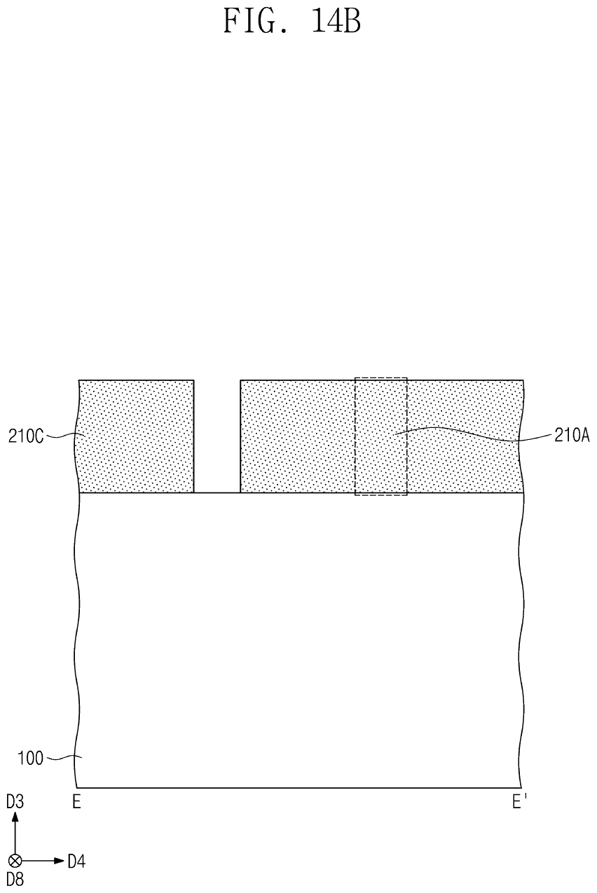

FIGS. 14A and 14B are cross-sectional views taken along a line D-D′ and a line E-E′ of FIG. 13, respectively. Referring to FIGS. 13, 14A, and 14B, the second portion 210B may be removed. The removal of the second portion 210B may include etching the first mask layer 220 and the line pattern 210 using the first protection pattern 310 and the fourth mask pattern 321 as a mask.

Next, remaining portions of the first protection pattern 310, the fourth mask pattern 321, and the first mask layer 220 may be removed. This may be performed through, for example, an ashing process.

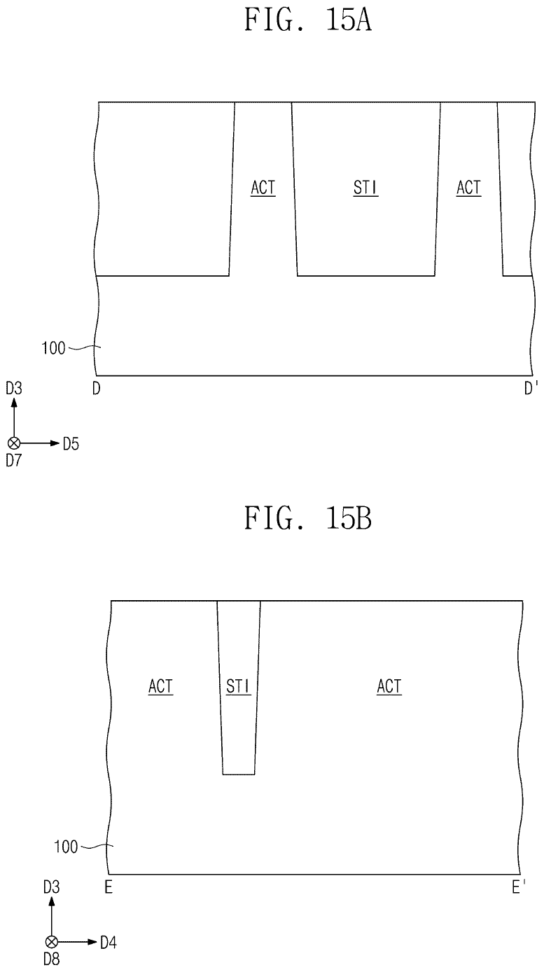

Referring to FIGS. 15A and 15B, the substrate 100 may be etched using the first portion 210A and the third portion 210C as a mask. The active patterns ACT may be formed as a result of the etching of the substrate 100, and then, the device isolation layer STI may be formed in an empty space between the active patterns ACT.

Referring back to FIGS. 1, 2, 3A, 3B, and 3C, the word lines WL may be formed on the active patterns ACT. Thereafter, the buffer pattern BP, the insulating pattern PP, the storage node contacts BC, the bit line contacts DC, the bit lines BL, the bit line capping patterns BCP, the bit line spacers BSP, the fence patterns FN, the landing pads LP, the filling pattern FIL, and the data storage patterns DSP may be formed.

In a method of fabricating a semiconductor device according to one or more embodiments of the disclosure, the line-shaped etching pattern 420B may be used to form the active patterns ACT, which are spaced apart from each other by a small and uniform distance. In addition, due to the first protection pattern 310 and the etching pattern 420B, a length of the active patterns ACT in the fourth direction D4 may be increased by removing only portions of the line pattern 210. Since the active patterns ACT are uniformly formed, the semiconductor device may be provided to have improved electrical and reliability characteristics.

### Embodiment 2

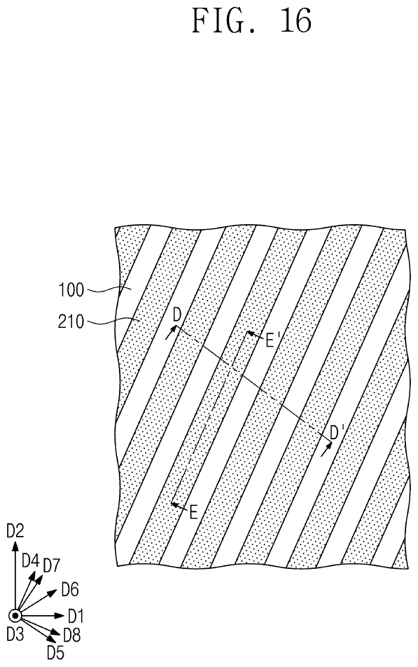

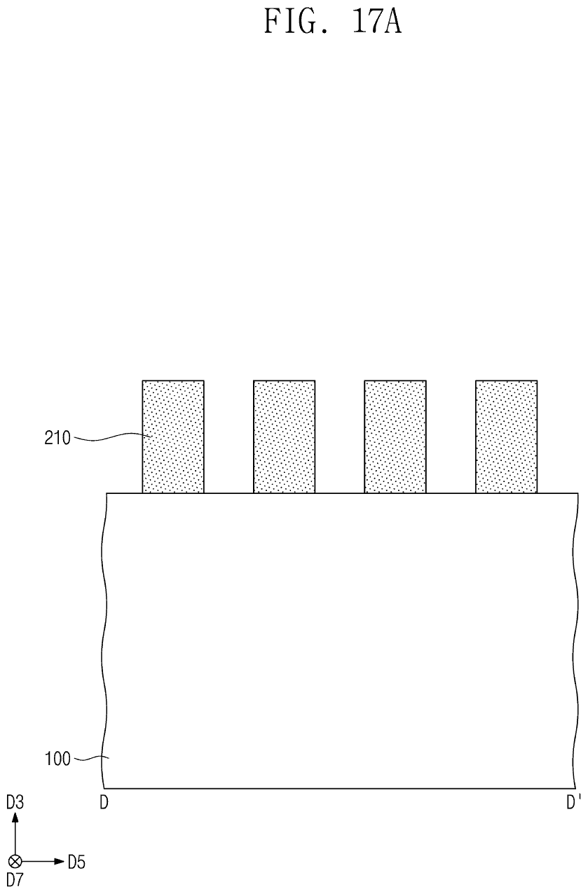

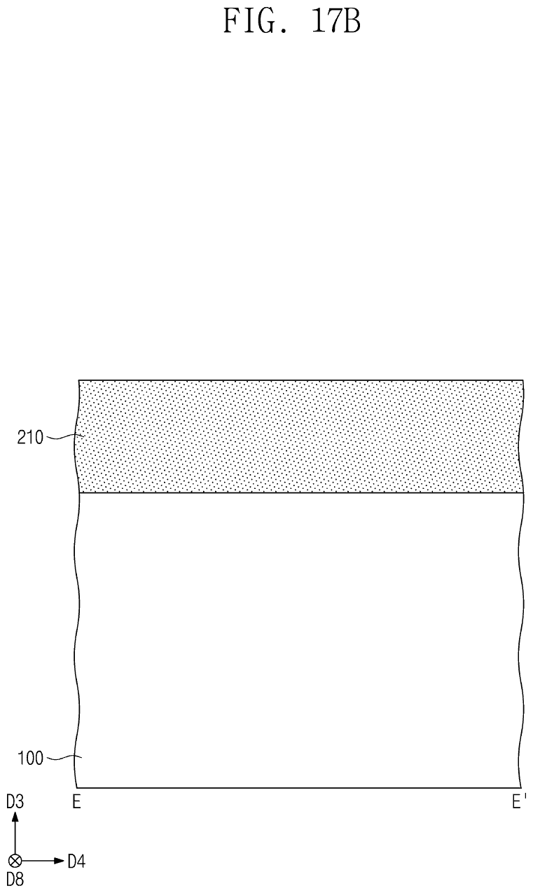

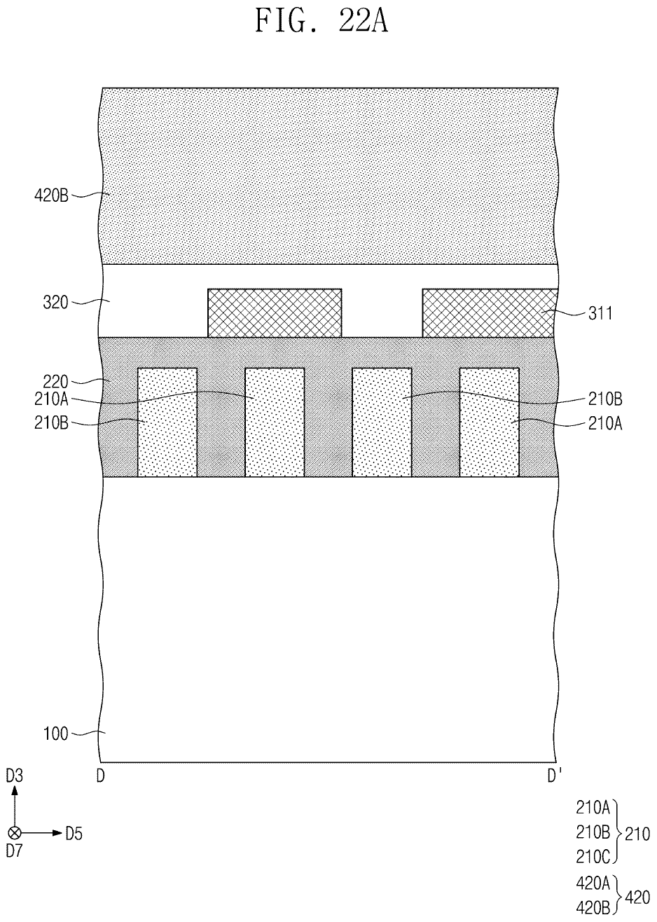

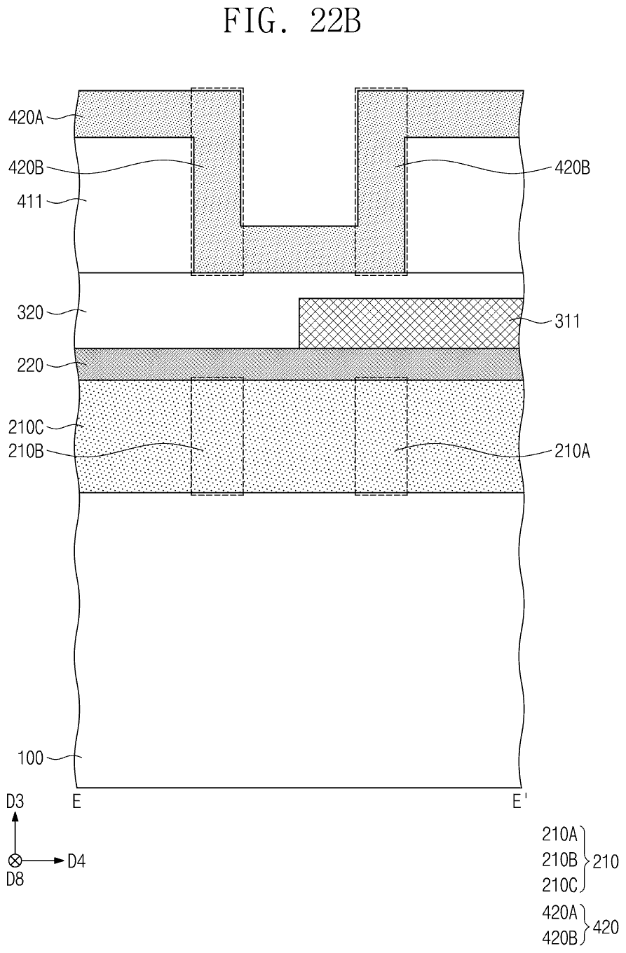

FIGS. 16, 18, 21, and 25 are an enlarged views illustrating a method of fabricating a semiconductor device according to one or more embodiments of the disclosure. FIGS. 17A, 17B, 19A, 19B, 20A, 20B, 22A, 22B, 23A, 23B, 24A, 24B, 26A, 26B, 27A, and 27B are cross-sectional views illustrating a method of fabricating a semiconductor device according to one or more embodiments of the disclosure.

FIGS. 17A and 17B are cross-sectional views taken along a line D-D′ and a line E-E′ of FIG. 16, respectively. Referring to FIGS. 16, 17A, and 17B, the line patterns 210 may be formed on the substrate 100.

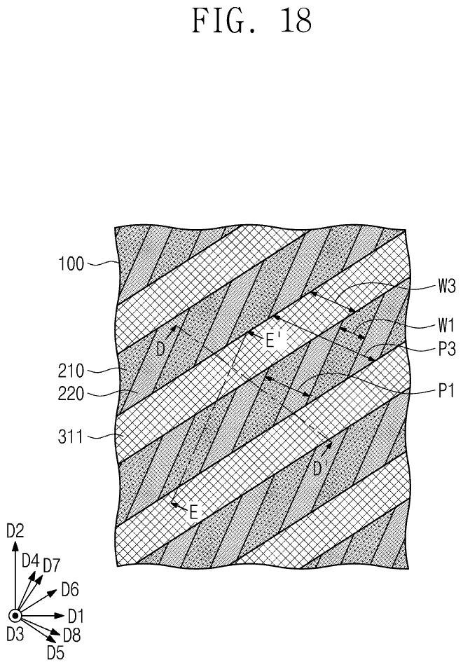

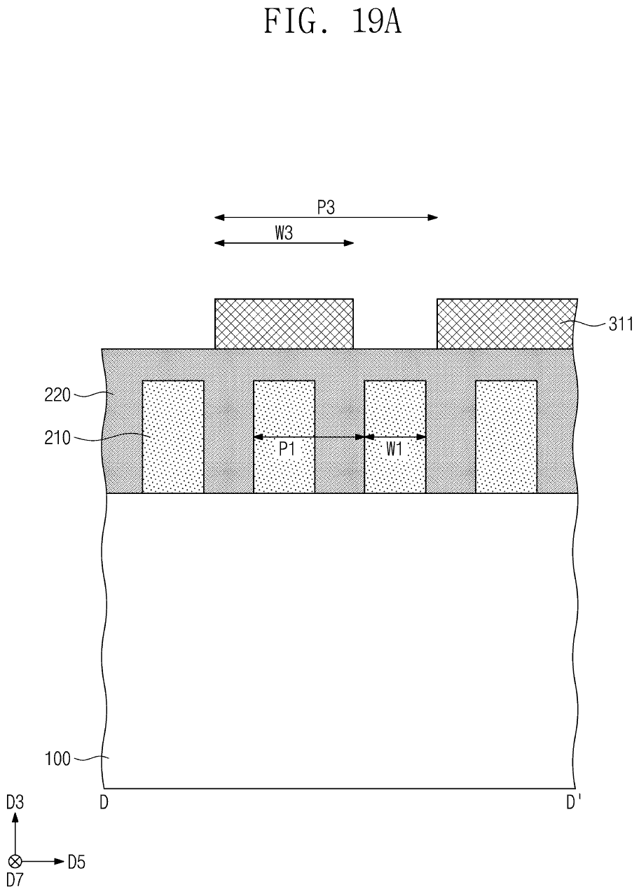

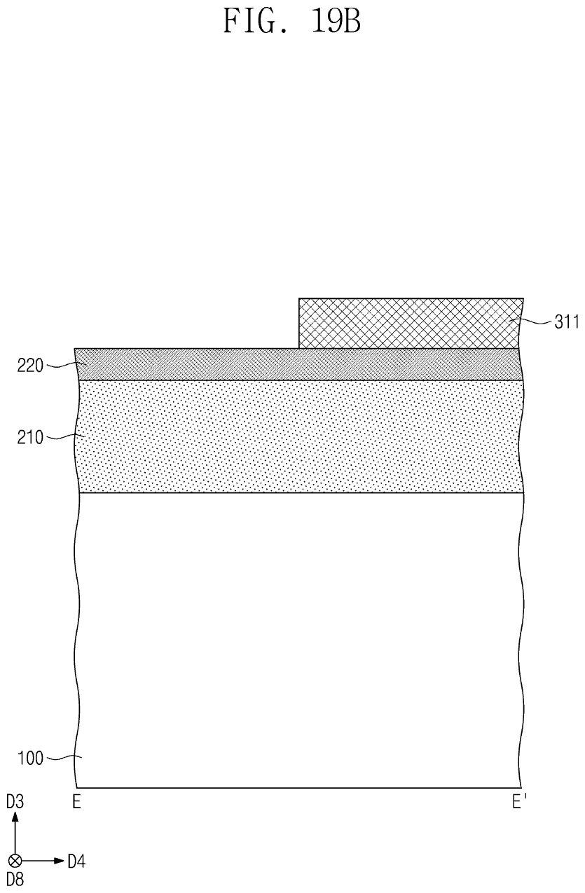

FIGS. 19A and 19B are cross-sectional views taken along a line D-D′ and a line E-E′ of FIG. 18, respectively. Referring to FIGS. 18, 19A, and 19B, the first mask layer 220 may be formed on the line patterns 210. A second protection pattern 311 may be formed on the first mask layer 220. The second protection pattern 311 may include an insulating material and/or a polymer.

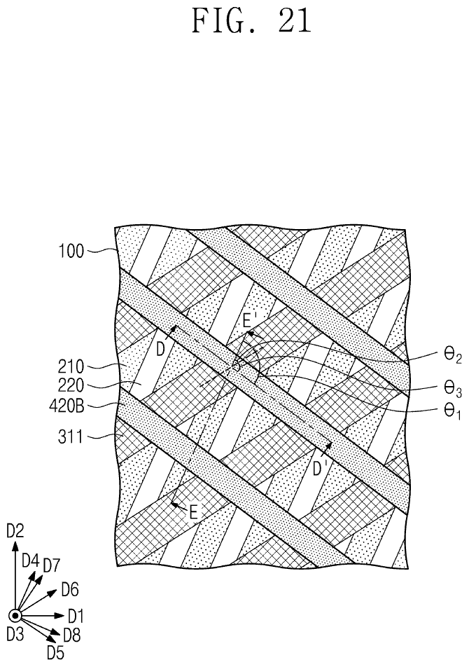

In an embodiment, a plurality of second protection patterns 311 may be formed. The second protection patterns 311 may be line-shaped patterns, which extend in the sixth direction D6 and are spaced apart from each other in a direction perpendicular to the sixth direction D6. The relationship between the sixth direction D6, the fourth direction D4, and the fifth direction D5 will be described in more detail with reference to FIG. 21.

A width W3 of the second protection pattern 311 in the fifth direction D5 may be greater than a width W1 of the line pattern 210. A distance between the second protection patterns 311 in the fifth direction D5 may be larger than the width W1 of the line pattern 210. In this case, it may be possible to clearly distinguish a portion of the line pattern 210, which is to be protected by the second protection pattern 311, from a portion of the line pattern 210, which is not to be protected by the second protection pattern 311.

The line patterns 210 may have a first pitch P1 in the fifth direction D5. The second protection patterns 311 may have a third pitch P3 in the fifth direction D5. In an embodiment, the third pitch P3 may be larger than the first pitch P1. As an example, the third pitch P3 may be 1.5 to 2.5 times the first pitch P1, but the disclosure is not limited to this example.

The formation of the second protection pattern 311 may include forming a protection layer (not shown) and patterning the protection layer. The patterning of the protection layer may include a photolithography process (e.g., an ArF photolithography process).

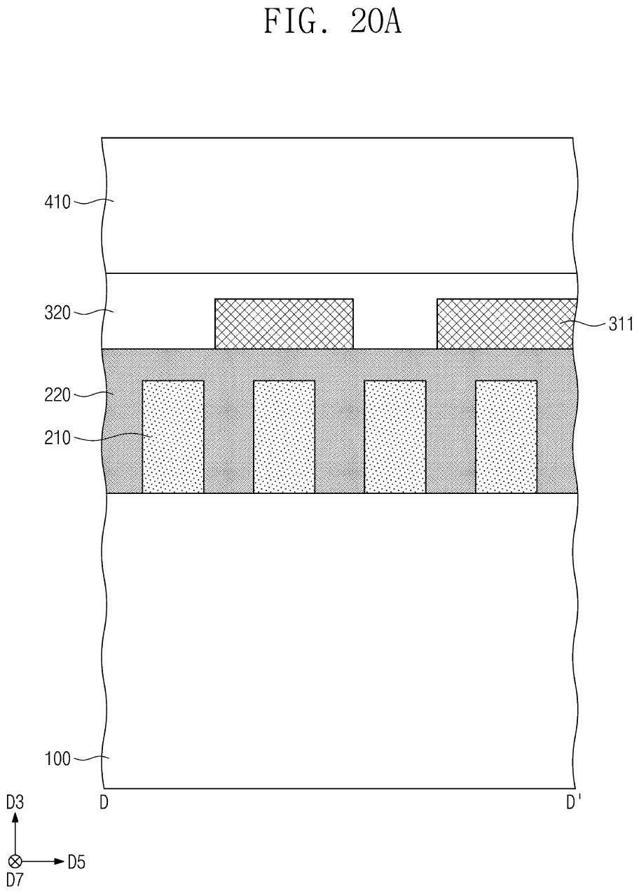

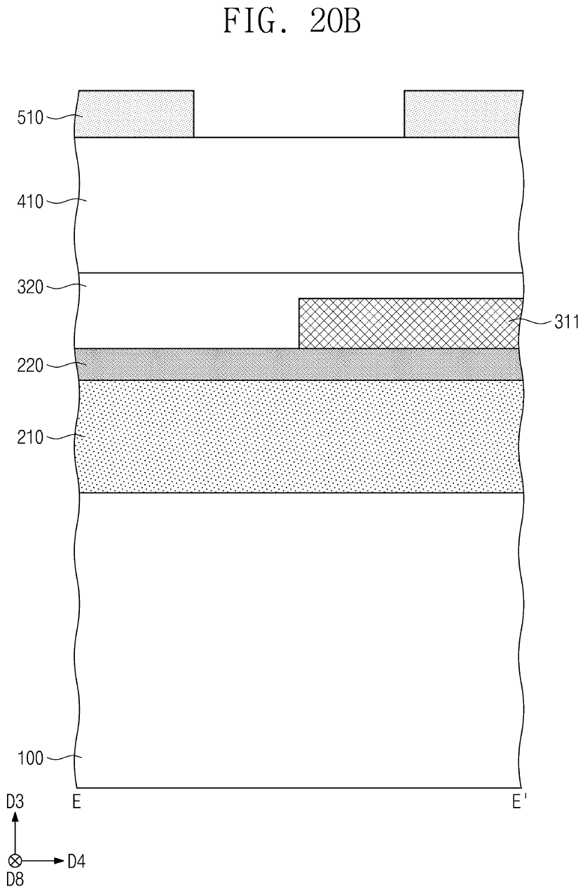

Referring to FIGS. 20A, 20B, 21, 22A, and 22B, the second mask layer 320 may be formed on the second protection pattern 311. The etching pattern 420B may be formed on the second mask layer 320. In an embodiment, the formation of the etching pattern 420B may include forming the third mask layer 410 on the second mask layer 320, forming the first mask pattern 510 on the third mask layer 410, removing a portion of the third mask layer 410 to form the second mask pattern 411, and forming the etching pattern 420B on the second mask pattern 411.

Each of the third mask layer 410 and the first mask pattern 510 may include an insulating material and/or a polymer. In an embodiment, the formation of the first mask pattern 510 may include forming a mask layer (not shown) and patterning the mask layer. The patterning of the mask layer may be performed through a photolithography process (e.g., an ArF photolithography process).

The second mask layer 320 may include an insulating material and/or a polymer. The second mask layer 320 may be formed of or include a material different from the second protection pattern 311. The second mask layer 320 may include a material having an etch selectivity with respect to the second protection pattern 311.

All of the fourth, fifth, and sixth directions D4, D5, and D6 may be parallel to the bottom surface of the substrate 100. The fourth, fifth, and sixth directions D4, D5, and D6 may satisfy the following [Equation 2].

$${θ}_{1} = {θ}_{2} + {θ}_{3} \qquad [ Equation 2 ]$$

where θ₁ is an angle between the fourth direction D4 and the fifth direction D5, θ₂ is an angle between the fourth direction D4 and the sixth direction D6, θ₃ is an angle between the fifth direction D5 and the sixth direction D6, and at least one of θ₂ and θ₃ is an acute angle. For example, the angle between the fourth and fifth directions D4 and D5 may range from 45° to 90° or may range from 70° to 80°.

The line pattern 210 may include the first portion 210A, the second portion 210B, and the third portion 210C. The first portion 210A may be defined as a portion of the line pattern 210, which is overlapped with both the second protection pattern 311 and the etching pattern 420B in the third direction D3. The second portion 210B may be defined as a portion of the line pattern 210, which is overlapped with the etching pattern 420B and is not overlapped with the second protection pattern 311 in the third direction D3. The third portion 210C may be defined as a portion of the line pattern 210, which is overlapped with the horizontal portion 420A or excludes the first and second portions 210A and 210B.

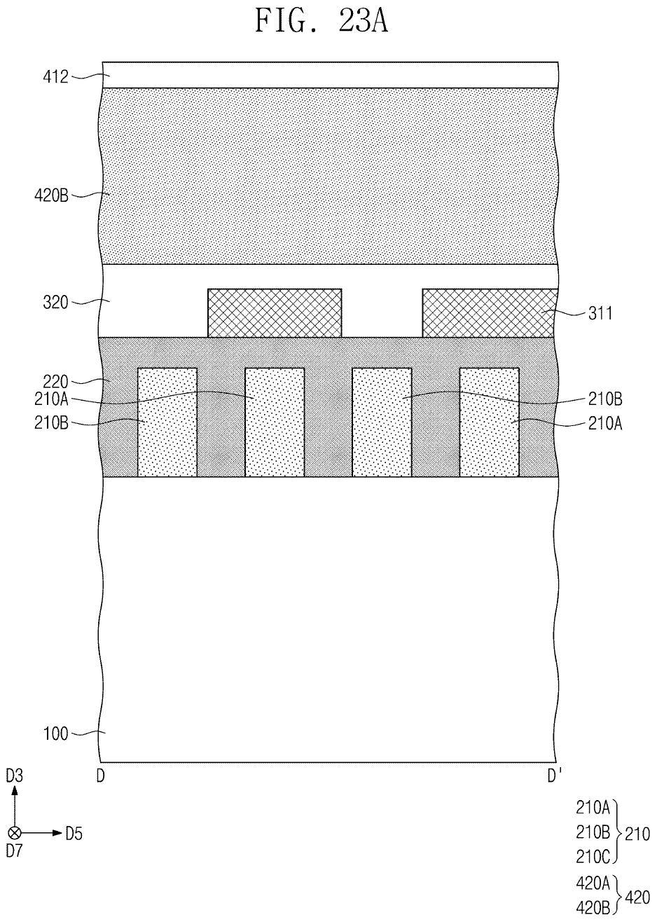

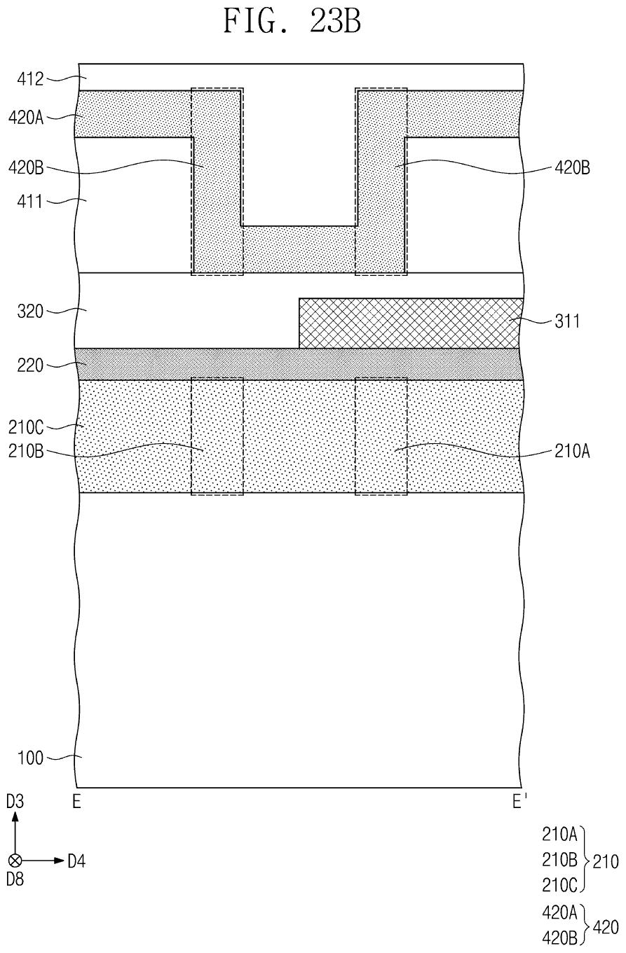

Referring to FIGS. 23A and 23B, the third mask pattern 412 may be formed on the etching structure 420.

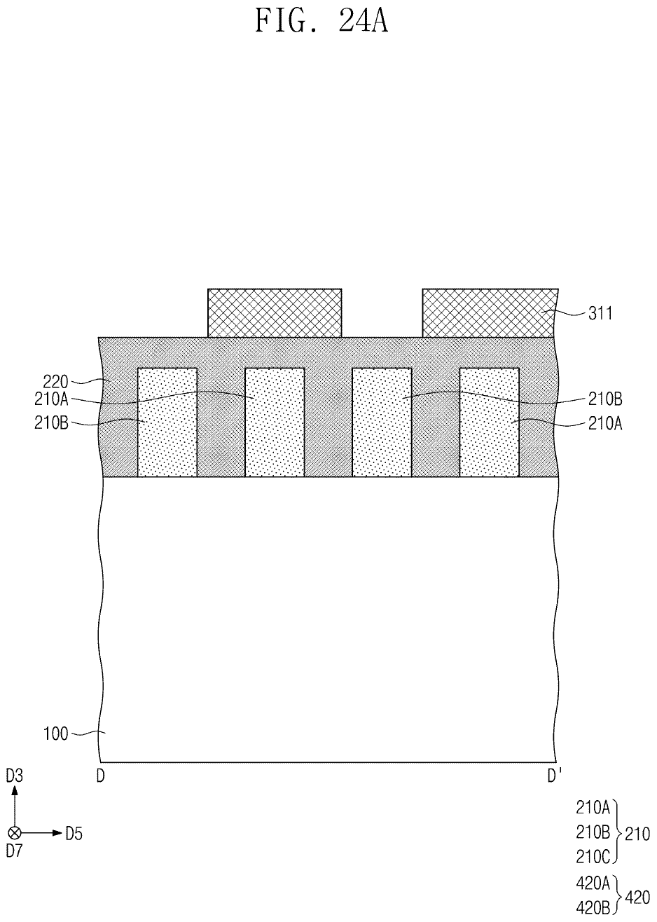

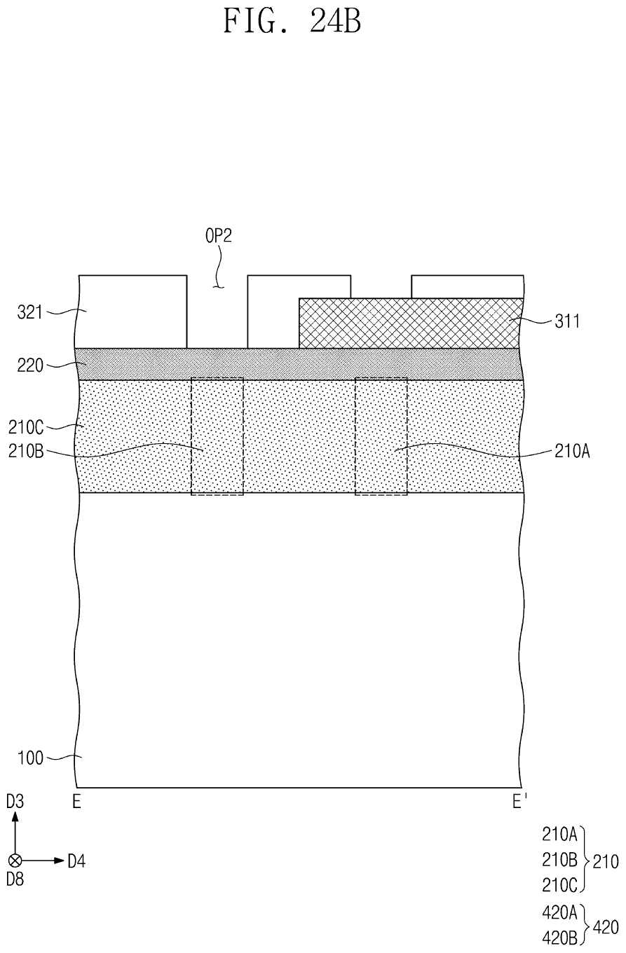

Referring to FIGS. 24A and 24B, the third mask pattern 412, the etching structure 420, the second mask pattern 411, and a portion of the second mask layer 320 may be removed.

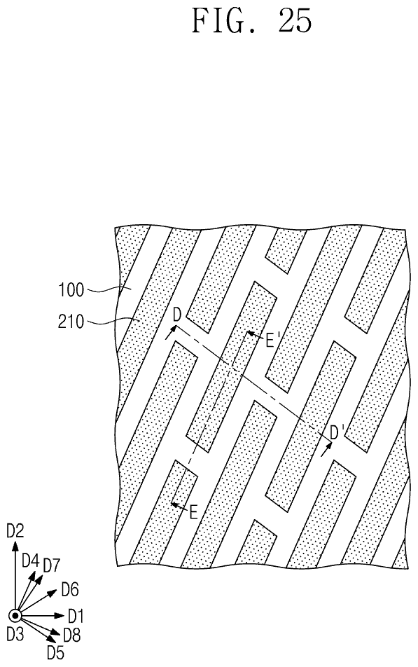

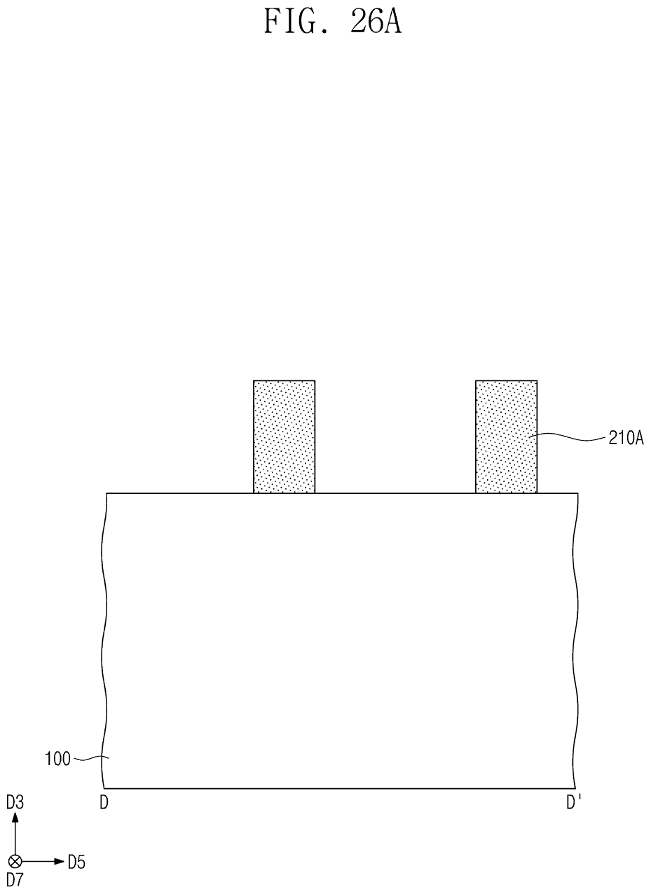

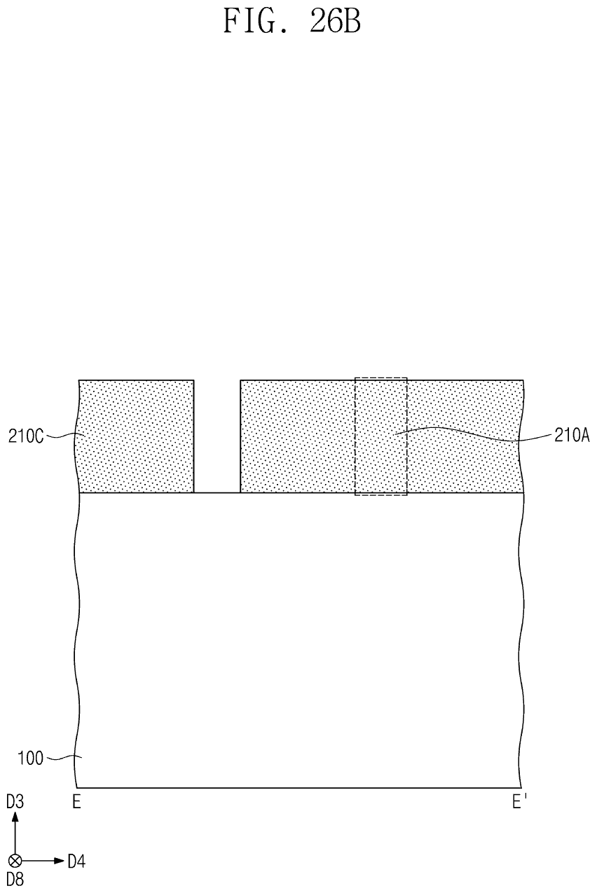

FIGS. 26A and 26B are cross-sectional views taken along a line D-D′ and a line E-E′ of FIG. 25, respectively. Referring to FIGS. 25, 26A, and 26B, the second portion 210B may be removed. The removal of the second portion 210B may include etching the first mask layer 220 and the line pattern 210 using the second protection pattern 311 and the fourth mask pattern 321 as a mask.

Next, remaining portions of the second protection pattern 311, the fourth mask pattern 321, and the first mask layer 220 may be removed. This may be performed through, for example, an ashing process.

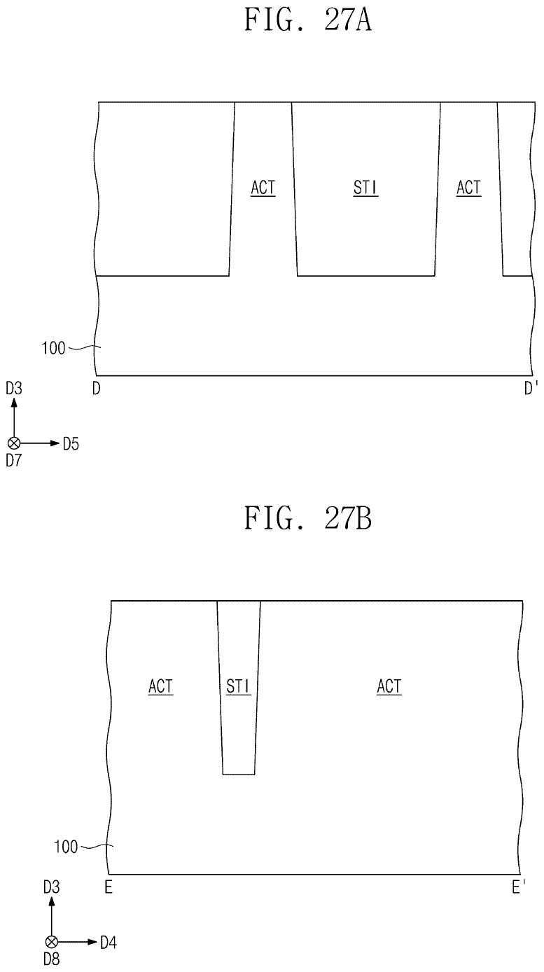

Referring to FIGS. 27A and 27B, the substrate 100 may be etched using the first portion 210A and the third portion 210C as a mask. The active patterns ACT may be formed as a result of the etching of the substrate 100, and then, the device isolation layer STI may be formed in an empty space between the active patterns ACT.

Referring back to FIGS. 1, 2, 3A, 3B, and 3C, the word lines WL may be formed on the active patterns ACT. Thereafter, the buffer pattern BP, the insulating pattern PP, the storage node contacts BC, the bit line contacts DC, the bit lines BL, the bit line capping patterns BCP, the bit line spacers BSP, the fence patterns FN, the landing pads LP, the filling pattern FIL, and the data storage patterns DSP may be formed.

In a method of fabricating a semiconductor device according to one or more embodiments of the disclosure, a line-shaped etching pattern may be used to form active patterns uniformly. In the semiconductor device fabrication method according to one or more embodiments of the disclosure, a protection pattern may be used to protect a portion of a line pattern from the etching pattern (or in a process of forming the line-shaped etching pattern), and thus, the active patterns may be uniformly formed. By uniformly forming the active patterns, it may be possible to provide a semiconductor device with improved electrical and reliability characteristics.

While example embodiments of the disclosure have been particularly shown and described, it will be understood by one of ordinary skill in the art that variations in form and detail may be made therein without departing from the spirit and scope of the attached claims and their equivalents.

What is claimed is:

1. A method of fabricating a semiconductor device, comprising forming active patterns on a substrate,
wherein the forming the active patterns comprises:
forming, on the substrate, a first line pattern and a second line pattern, which extend in a first direction and are spaced apart from each other in a second direction perpendicular to the first direction;
selectively forming a protection pattern on the first line pattern;
forming an etching pattern on the first line pattern and the second line pattern, the etching pattern extending in a third direction crossing the first direction and the second direction; and
removing a portion of the second line pattern overlapped with the etching pattern.

2. The method of claim 1, wherein the selectively forming the protection pattern comprises:
forming a mask layer on the first line pattern and the second line pattern; and
forming the protection pattern on the mask layer,
wherein the protection pattern comprises a plurality of openings exposing the mask layer.

3. The method of claim 2, wherein a width of each of the plurality of openings in the third direction is larger than a width of the first line pattern or the second line pattern in the third direction.

4. The method of claim 1, wherein the protection pattern comprises a plurality of protection patterns, which are spaced apart from each other.

5. The method of claim 1, wherein the protection pattern extends in a fourth direction crossing the first direction and the third direction, and
wherein the fourth direction satisfies the following equation:
θ₁=θ₂+θ₃,
where θ₁ is an angle between the first direction and the third direction, θ₂ is an angle between the first direction and the fourth direction, θ₃ is an angle between the third direction and the fourth direction, and at least one of θ₂ and θ₃ is an acute angle.

6. The method of claim 1, wherein an angle between the first direction and the third direction ranges from 70° to 90°.

7. A method of fabricating a semiconductor device, comprising forming active patterns on a substrate,
wherein the forming the active patterns comprises:
forming, on the substrate, a line pattern extending in a first direction;
forming a protection pattern on the line pattern;
forming, on the line pattern, etching patterns, which extend in a second direction crossing the first direction and are spaced apart from each other in the first direction, the line pattern comprising a first portion and a second portion, which are overlapped with the etching patterns, the protection pattern being between the first portion and the etching patterns; and
removing the second portion.

8. The method of claim 7, further comprising:
forming a device isolation pattern between the active patterns; and
forming a word line on the active patterns.

9. The method of claim 7, wherein the forming the etching patterns is performed through an ArF lithography process.

10. The method of claim 7, wherein the forming the protection pattern is performed through an extreme ultraviolet (EUV) lithography process.

11. The method of claim 7, wherein the forming the protection pattern is performed through an Argon Fluoride (ArF) lithography process.

12. The method of claim 7, wherein, prior to the removing the second portion, the second portion is exposed from the protection pattern.

13. A method of fabricating a semiconductor device, comprising forming active patterns on a substrate,
wherein the forming the active patterns comprises:
forming, on the substrate, line patterns, which extend in a first direction and are spaced apart from each other in a second direction perpendicular to the first direction;
forming a protection pattern on the line patterns;
forming, on the line patterns, etching patterns extending in a third direction crossing the first direction and the second direction, each of the line patterns comprising a first portion and a second portion, which are overlapped with the etching patterns, the protection pattern being between the first portion and the etching patterns; and
selectively removing the second portion.

14. The method of claim 13, wherein the forming the protection pattern comprises:
forming a mask layer on the line patterns; and
forming the protection pattern on the mask layer,
wherein the protection pattern comprises openings exposing the mask layer.

15. The method of claim 14, wherein the openings are spaced apart from each other in the first direction and the third direction.

16. The method of claim 14, wherein the openings are disposed in a zigzag shape when viewed in a plan view.

17. The method of claim 14, wherein the line patterns has a first pitch in the third direction,
wherein each of the openings has a second pitch in the third direction, and
wherein the second pitch is larger than the first pitch.

18. The method of claim 17, wherein the second pitch is 1.5 to 2.5 times the first pitch.

19. The method of claim 13, wherein the protection pattern comprises a plurality of protection patterns extending in a fourth direction and are spaced apart from each other,
wherein each of the line patterns has a first pitch in the third direction,
wherein the protection pattern has a second pitch in the third direction, and
wherein the second pitch is larger than the first pitch.

20. The method of claim 19, wherein the second pitch is 1.5 to 2.5 times the first pitch.
